(19) United States
(12) Patent Application Publication
(10) Pub. No.: US 2026/0173794 A1
(43) Pub. Date: Jun. 18, 2026

(54) SUBSTRATE TREATMENT APPARATUS AND GUARD DETERMINATION METHOD

(71) Applicant: SCREEN Holdings Co., Ltd., Kyoto (JP)

(72) Inventors: Shinji SHIMIZU, Kyoto-shi, Kyoto (JP); Tatsuya MASUI, Kyoto-shi, Kyoto (JP); Yuichi DEBA, Kyoto-shi, Kyoto (JP); Miwa MIYAWAKI, Kyoto-shi, Kyoto (JP)

(21) Appl. No.: 18/711,450

(22) PCT Filed: Nov. 18, 2022
(86) PCT No.: PCT/JP2022/042841

§ 371 Date: May 17, 2024

(30) Foreign Application Priority Data
Dec. 1, 2021 (JP) 2021-195739

(51) Int. Cl. H10P 72/00

(52) U.S. Cl. CPC H10P 72/0448; H10P 72/0424

(57) ABSTRACT

A substrate treatment apparatus includes: a substrate holder that holds a substrate; a liquid nozzle that supplies a treatment liquid to the substrate held by the substrate holder; a guard that has a cylindrical shape, surrounds the substrate holder, and receives the treatment liquid scattered from a peripheral edge of the substrate; a guard raising and lowering mechanism that raises and lowers the guard; a camera that is provided obliquely above the substrate holder and captures an image of an image capturing region including the guard to generate a captured image; and a controller that outputs a control signal for moving the guard to a predetermined height position to the guard raising and lowering mechanism, and determines presence or absence of an abnormality related to a position or a shape of the guard based on the captured image.

### TECHNICAL FIELD

The present disclosure relates to a substrate treatment apparatus and a guard determination method.

### BACKGROUND ART

Conventionally, in a manufacturing process of a semiconductor device or the like, various treatment liquids such as pure water, a photoresist liquid, and an etching liquid are supplied to a substrate to perform various substrate treatments such as a cleaning treatment and a resist coating treatment. As an apparatus for performing a substrate treatment using these treatment liquids, a substrate treatment apparatus that discharges a treatment liquid from a nozzle to a surface of the substrate while rotating the substrate in a horizontal posture is widely used.

In such a substrate treatment apparatus, whether or not the treatment liquid is discharged from the nozzle is checked. As a method for determining the presence or absence of discharge, for example, Patent Documents 1 and 2 propose that imaging capturing means such as a camera is provided to monitor discharge of a treatment liquid from a nozzle.

### PRIOR ART DOCUMENTS

### Patent Documents

Patent Document 1: Japanese Patent Application Laid-Open No. 2008-135679

Patent Document 2: Japanese Patent Application Laid-Open No. 2015-173148

### SUMMARY

### Problem to be Solved by the Invention

In order to appropriately treat the substrate, it is desirable to monitor not only the treatment liquid but also more monitoring targets.

For example, the substrate treatment apparatus is provided with a guard for receiving the treatment liquid scattered from the peripheral edge of the substrate. The guard has a cylindrical shape and can surround the substrate. The guard is provided so as to be capable of being raised and lowered, and the guard is lowered when the substrate is carried in and out. As a result, it is possible to avoid collision between a transport robot for carrying the substrate in and out of the substrate treatment apparatus and the guard. When the treatment liquid is supplied to the surface of the substrate, the guard raises. The upper end peripheral edge portion of the guard is located above the substrate due to the raising of the guard. Therefore, the treatment liquid scattered from the peripheral edge of the substrate is received by the inner peripheral surface of the guard.

If an abnormality occurs and the guard cannot move to an appropriate position, collision between the guard and the transport robot cannot be appropriately avoided, or the treatment liquid cannot be appropriately received by the guard.

In order to detect such a position abnormality of the guard, an internal sensor of a guard raising and lowering mechanism for raising and lowering the guard can be used. For example, when the guard raising and lowering mechanism includes a power relay mechanism such as a ball screw mechanism and a power source such as a motor, an encoder that detects a rotational position of the motor can be used for detecting a position abnormality. However, if the motor steps out or an abnormality occurs in the ball screw mechanism, the correspondence relationship between the rotational position of the motor and the position of the guard changes, and the accuracy of the position detection of the guard decreases. For this reason, the detection accuracy of the position abnormality of the guard also decreases.

In addition, even if the shape of the guard is deformed due to an abnormality, the transfer robot and the hand may collide with each other, or the treatment liquid may not be appropriately received.

Therefore, an object of the present disclosure is to provide a technique capable of detecting an abnormality related to a guard with higher accuracy.

### Means to Solve the Problem

A first aspect is a substrate treatment apparatus including: a substrate holder that holds a substrate; a liquid nozzle that supplies a treatment liquid to the substrate held by the substrate holder; a guard that has a cylindrical shape, surrounds the substrate holder, and receives the treatment liquid scattered from a peripheral edge of the substrate; a guard raising and lowering mechanism that raises and lowers the guard; a camera that is provided obliquely above the substrate holder and captures an image of an image capturing region including the guard to generate a captured image; and a controller that outputs a control signal for moving the guard to a predetermined height position to the guard raising and lowering mechanism, and determines presence or absence of an abnormality related to a position or a shape of the guard based on the captured image.

A second aspect is the substrate treatment apparatus according to the first aspect, in which the controller determines presence or absence of the abnormality based on a determination region including a part of the guard in the captured image.

A third aspect is the substrate treatment apparatus according to the second aspect, in which the determination region includes a first determination region and a second determination region, in which the first determination region and the second determination region are set on opposite sides to each other with respect to a minor axis of a virtual ellipse along an upper end peripheral edge portion of the guard in the captured image, and in which the controller determines that the guard is normal when temporarily determining that the guard is normal in both the first determination region and the second determination region.

A fourth aspect is the substrate treatment apparatus according to the second or third aspect, in which the determination region includes at least a part of an upper end peripheral edge portion of the guard when the guard is located at the predetermined height position, and is set to a region not including the substrate.

A fifth aspect is the substrate treatment apparatus according to any one of the second to fourth aspects, in which the predetermined height position is a guard standby position where an upper end peripheral edge portion of the guard is lower than an upper surface of a spin base of the substrate holder facing a lower surface of the substrate in a vertical direction, and in which the determination region is set to a region including at least a part of a peripheral edge portion on a front side as viewed from the camera in the upper end peripheral edge portion of the guard when the guard is located at the predetermined height position.

A sixth aspect is the substrate treatment apparatus according to any one of the second to fourth aspects, in which the predetermined height position is a guard treatment position where an upper end peripheral edge portion of the guard is above an upper surface of the substrate held by the substrate holder, and in which the determination region is set to a region including a peripheral edge portion on a back side as viewed from the camera in the upper end peripheral edge portion of the guard when the guard is located at the predetermined height position.

A seventh aspect is the substrate treatment apparatus according to the sixth aspect, in which the controller moves at least one of a plurality of the guards to the guard treatment position, and in which the determination region is set to a region including the upper end peripheral edge portion of each of the plurality of guards when each of the plurality of guards is located at the guard treatment position.

An eighth aspect is the substrate treatment apparatus according to any one of the second to seventh aspects, in which the controller determines that the guard is normal when similarity between the determination region and a normal reference image is equal to or greater than a threshold, and in which the threshold is set to be lower than a value of similarity between the determination region of the captured image captured when the guard is located at the predetermined height position and a droplet is attached to the guard and the reference image.

A ninth aspect is the substrate treatment apparatus according to any one of the first to eighth aspects, further including a gas nozzle that supplies gas to the guard to blow off droplet attached to the guard.

A tenth aspect is the substrate treatment apparatus according to any one of the second to seventh aspects, further including a gas nozzle that supplies gas to the guard to blow off droplet attached to the guard, in which the controller includes: a first step of determining that the guard is normal when similarity between the determination region and a normal reference image is equal to or greater than a second threshold higher than a first threshold; a second step of supplying gas to the gas nozzle toward a portion to be captured of the guard that appears in the determination region when the similarity is less than the second threshold and equal to or greater than the first threshold; a third step of causing the camera to capture the image capturing region and generate the captured image after the second step; and a fourth step of determining presence or absence of the abnormality based on the similarity between the determination region of the captured image generated in the third step and the reference image, in which the first threshold is set to be lower than a first value of similarity between the determination region of the captured image captured when the guard is located at the predetermined height position and a droplet is attached to the portion to be captured of the guard and the reference image, and in which the second threshold is set to be lower than a second value of similarity between the determination region of the captured image captured when the guard is located at the predetermined height position and no droplets are attached to the portion to be captured of the guard and the reference image, and to be higher than the first value.

An eleventh aspect is a guard determination method including: a guard raising and lowering step of moving a guard that has a cylindrical shape and surrounds a substrate holder for holding a substrate to a predetermined height position; an image capturing step of capturing an image of an image capturing region including the guard by a camera provided above the substrate holder and generating a captured image; and a determination step of determining whether or not an abnormality related to a position or a shape of the guard has occurred based on the captured image.

A twelfth aspect is the guard determination method according to the eleventh aspect, in which, in the determination step, the presence or absence of the abnormality is determined based on a determination region including a part of the guard in the captured image.

A thirteenth aspect is the guard determination method according to the twelfth aspect, in which the determination region includes a first determination region and a second determination region, in which the first determination region and the second determination region are set on opposite sides to each other with respect to a minor axis of a virtual ellipse along an upper end peripheral edge portion of the guard in the captured image, and in which, in the determination step, it is determined that the guard is normal when temporarily determining that the guard is normal in both the first determination region and the second determination region.

A fourteenth aspect is the guard determination method according to the twelfth or thirteenth aspect, in which the determination region includes at least a part of an upper end peripheral edge portion of the guard when the guard is located at the predetermined height position, and is set to a region not including the substrate.

A fifteenth aspect is the guard determination method according to any one of the twelfth to fourteenth aspects, in which the predetermined height position is a guard standby position where an upper end peripheral edge portion of the guard is lower than an upper surface of a spin base of the substrate holder facing a lower surface of the substrate in a vertical direction, and in which the determination region is set to a region including at least a part of a peripheral edge portion on a front side as viewed from the camera in the upper end peripheral edge portion of the guard when the guard is located at the predetermined height position.

A sixteenth aspect is the guard determination method according to any one of the twelfth to fourteenth aspects, in which the predetermined height position is a guard treatment position where an upper end peripheral edge portion of the guard is above an upper surface of the substrate held by the substrate holder, and in which the determination region is set to a region including a peripheral edge portion on a back side as viewed from the camera in the upper end peripheral edge portion of the guard when the guard is located at the predetermined height position.

A seventeenth aspect is the guard determination method according to the sixteenth aspect, in which, in the guard raising and lowering step, at least one of a plurality of the guards is moved to the guard treatment position, and in which the determination region is set to a region including the upper end peripheral edge portion of each of the plurality of guards when each of the plurality of guards is located at the guard treatment position.

An eighteenth aspect is the guard determination method according to any one of the twelfth to seventeenth aspects, in which, in the determination step, it is determined that the guard is normal when similarity between the determination region and a normal reference image is equal to or greater than a threshold, and in which the threshold is set to be lower than a value of similarity between the determination region of the captured image captured when the guard is located at the predetermined height position and a droplet is attached to the guard and the reference image.

A nineteenth aspect is the guard determination method according to any one of the eleventh to eighteenth aspects, further including a gas supply step of blowing off droplet attached to the guard with gas before the image capturing step.

A twentieth aspect is the guard determination method according to any one of twelfth to seventeenth aspects, in which the determination step includes: a first step of determining that the guard is normal when similarity between the determination region and a normal reference image is equal to or greater than a second threshold higher than a first threshold; a second step of supplying gas to a portion to be captured of the guard that appears in the determination region when the similarity is less than the second threshold and equal to or greater than the first threshold; a third step of capturing, by the camera, the image capturing region and generate the captured image after the second step; and a fourth step of determining presence or absence of the abnormality based on the similarity between the determination region of the captured image generated in the third step and the reference image, in which the first threshold is set to be lower than a first value of similarity between the determination region of the captured image captured when the guard is located at the predetermined height position and a droplet is attached to the portion to be captured of the guard and the reference image, and in which the second threshold is set to be lower than a second value of similarity between the determination region of the captured image captured when the guard is located at the predetermined height position and no droplet are attached to the portion to be captured of the guard and the reference image, and to be higher than the first value.

### Effects of the Invention

According to the first and eleventh aspects, since the presence or absence of the abnormality is determined based on the captured image including the guard, the presence or absence of the abnormality can be determined with higher determination accuracy.

According to the second and twelfth aspects, since the configuration included in the area other than the determination region does not affect the determination, the presence or absence of the abnormality can be determined with higher determination accuracy.

According to the third and thirteenth aspects, determination accuracy can be improved. For example, when the guard is temporarily determined to be normal in one of the first determination region and the second determination region, such as when the guard is inclined, it can be temporarily determined that an abnormality has occurred in the other. According to the third and thirteenth aspects, even in this case, the guard is correctly determined to be abnormal. Therefore, the determination accuracy can be improved.

According to the fourth and fourteenth aspects, since the substrate is not included, the determination accuracy is not affected by the presence or absence of the substrate, and the presence or absence of the abnormality can be determined with high determination accuracy.

According to the fifth and fifteenth aspects, it is easy to set the determination region to a region that does not include the substrate and includes the upper end peripheral edge portion of the guard.

According to the sixth and sixteenth aspects, it is easy to set the determination region to a region that does not include the substrate and includes the upper end peripheral edge portion of the guard.

According to the seventh and seventeenth aspects, since the determination region is set to a region including the upper end peripheral edge portions of the plurality of guards, the presence or absence of the abnormality of the plurality of guards can be determined.

According to the eighth, ninth, eighteenth, and nineteenth aspects, erroneous determination by droplet can be suppressed.

According to the tenth and twentieth aspects, when the similarity is less than the second threshold and equal to or greater than the first threshold, there is a possibility that no abnormality occurs and the droplet is attached to the portion to be captured. In this situation, gas is supplied to the portion to be captured of the guard. Therefore, if the droplet is attached to the portion to be captured, the droplet is blown off by the gas. Then, in the third step, it is possible to obtain a captured image in a state in which no droplets are attached to the portion to be captured, and thus, it is possible to determine the presence or absence of the abnormality with higher determination accuracy in the fourth step.

In addition, since the gas is supplied in a situation where there is a possibility that droplet is attached, the consumption amount of the gas can be reduced.

### BRIEF DESCRIPTION OF DRAWINGS

FIG. 1 is a plan view schematically illustrating an example of a configuration of a substrate treatment apparatus.

FIG. 2 is a plan view schematically illustrating an example of a configuration of a treatment unit.

FIG. 3 is a longitudinal sectional view schematically illustrating an example of the configuration of the treatment unit.

FIG. 4 is a functional block diagram schematically illustrating an example of an internal configuration of a controller.

FIG. 5 is a flowchart illustrating an example of a flow of a substrate treatment.

FIG. 6 is a view schematically illustrating an example of a state in the treatment unit in a chemical liquid treatment.

FIG. 7 is a flowchart illustrating an example of guard monitoring processing according to a first embodiment.

FIG. 8 is a view schematically illustrating an example of captured images.

FIG. 9 is a view schematically illustrating an example of captured images.

FIG. 10 is a flowchart illustrating an example of more specific operation of the determination step.

FIG. 11 is a view schematically illustrating an example of captured images when a middle guard and an outer guard stop at respective guard treatment positions.

FIG. 12 is a view schematically illustrating an example of captured images when an inner guard, the middle guard, and the outer guard stop at the respective guard treatment positions.

FIG. 13 is a view schematically illustrating an example of captured images when droplets are attached to an outer peripheral surface of a guard portion.

FIG. 14 is a bar graph schematically illustrating similarity as an experimental result.

FIG. 15 is a view schematically illustrating an example of a configuration of a treatment unit according to a second embodiment.

FIG. 16 is a flowchart illustrating an example of guard monitoring processing according to the second embodiment.

FIG. 17 is a flowchart illustrating a modification of the guard monitoring processing according to the second embodiment.

### DESCRIPTION OF EMBODIMENTS

Hereinafter, embodiments will be described with reference to the accompanying drawings. Note that the drawings are schematically illustrated, and omission of the configuration or simplification of the configuration is appropriately made for convenience of description. In addition, the mutual relationship between the sizes and positions of the configurations illustrated in the drawings is not necessarily accurately described, and can be appropriately changed.

Furthermore, in the following description, similar components are denoted by the same reference numerals, and names and functions thereof are also similar. Therefore, detailed description thereof may be omitted in order to avoid duplication.

In addition, in the following description, even if ordinal numbers such as “first” or “second” are used, these terms are used for convenience to facilitate understanding of the contents of the embodiments, and are not limited to the order or the like that can be caused by these ordinal numbers.

Where expressions indicating a relative or absolute positional relationship (e.g., “in one direction”, “along one direction”, “parallel”, “orthogonal”, “center”, “concentric”, “coaxial”, etc.) are used, the expressions shall not only strictly represent the positional relationship, but also represent a state of being displaced relative to an angle or distance to the extent that a tolerance or comparable function is obtained, unless otherwise specified. When an expression indicating an equal state (for example, “same”, “equal”, “homogeneous”, or the like) is used, unless otherwise specified, the expression not only represents a quantitatively strictly equal state, but also represents a state in which there is a difference in obtaining a tolerance or a similar function. In a case where an expression indicating a shape (for example, “quadrangular” or “cylindrical”) is used, unless otherwise specified, the expression not only represents the shape geometrically and strictly, but also represents a shape having, for example, unevenness or chamfering within a range in which the same level of effect can be obtained. When the expression “comprising”, “including”, “provided with”, “containing”, or “having” one component is used, the expression is not an exclusive expression excluding the presence of other components. When the expression “at least any one of A, B, and C” is used, the expression includes only A, only B, only C, any two of A, B, and C, and all of A, B, and C.

### First Embodiment

### Overall Configuration of Substrate Treatment Apparatus

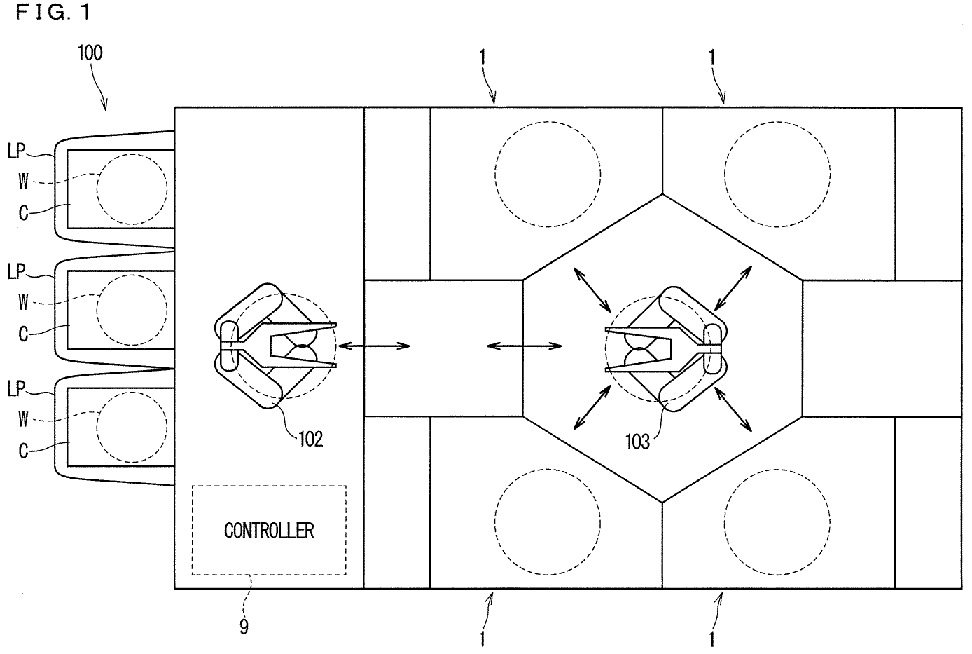

FIG. 1 is a plan view schematically illustrating an example of a configuration of a substrate treatment apparatus 100. The substrate treatment apparatus 100 is a single wafer type treatment apparatus that treats substrates W to be treated one by one. The substrate treatment apparatus 100 performs a liquid treatment on the substrate W using a chemical liquid and a rinse liquid such as pure water, and then performs a drying treatment. The substrate W is, for example, a semiconductor substrate and has a disk shape. As the chemical liquid, for example, a mixed solution of ammonia and a hydrogen peroxide solution (SC1), a mixed aqueous solution of hydrochloric acid and a hydrogen peroxide solution (SC2), or a DHF solution (dilute hydrofluoric acid) is used. In the following description, a chemical liquid, a rinse liquid, an organic solvent, and the like are collectively referred to as a “treatment liquid”. Note that a chemical liquid for not only the cleaning treatment but also removing an unnecessary film, a chemical liquid for etching, or the like is included in the “treatment liquid”.

The substrate treatment apparatus 100 includes a plurality of treatment units 1, a load port LP, an indexer robot 102, a main conveyance robot 103, and a controller 9.

The load port LP is an interface unit for carrying in and out the substrate W between the substrate treatment apparatus 100 and the outside. A container (also referred to as a carrier) accommodating a plurality of untreated substrates W is carried into the load port LP from the outside. The load port LP can hold a plurality of carriers. As described later, each substrate W is taken out from the carrier by the substrate treatment apparatus 100, treated, and accommodated in the carrier again. The carrier accommodating the plurality of treated substrates W is carried out from the load port LP to the outside.

As the carrier, a front opening unified pod (FOUP) that houses the substrate W in a sealed space, a standard mechanical inter face pod (SMIF), or an open cassette (OC) that exposes the substrate W to outside air may be adopted.

The indexer robot 102 conveys the substrate W between each carrier held in the load port LP and the main conveyance robot 103. The main conveyance robot 103 conveys the substrate W between each treatment unit 1 and the indexer robot 102.

The treatment unit 1 performs liquid treatment and drying treatment on one substrate W. In the substrate treatment apparatus 100 according to the present embodiment, 12 treatment units 1 having the same configuration are arranged. Specifically, four towers each including three treatment units 1 stacked in the vertical direction are arranged so as to surround the periphery of the main conveyance robot 103. In FIG. 1, one of the treatment units 1 superimposed in three stages is schematically illustrated Note that the number of treatment units 1 in the substrate treatment apparatus 100 is not limited to 12, and may be appropriately changed.

The main conveyance robot 103 is installed at the center of the four towers in which the treatment units 1 are stacked. The main conveyance robot 103 carries the substrate W to be treated received from the indexer robot 102 into each treatment unit 1. In addition, the main conveyance robot 103 carries out the treated substrate W from each treatment unit 1 and transfers the substrate W to the indexer robot 102. The controller 9 controls the operation of each component of the substrate treatment apparatus 100.

Hereinafter, one of the 12 treatment units 1 mounted on the substrate treatment apparatus 100 will be described, but the other treatment units 1 have the same configuration except that the arrangement relationship of the nozzles is different.

### Treatment Unit

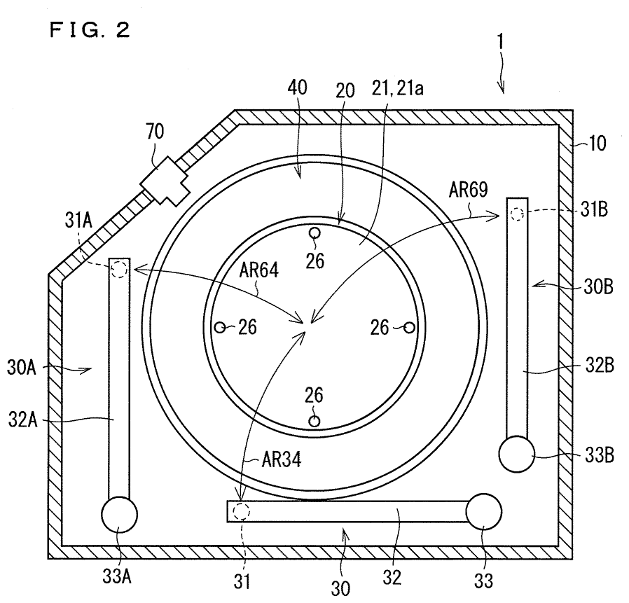

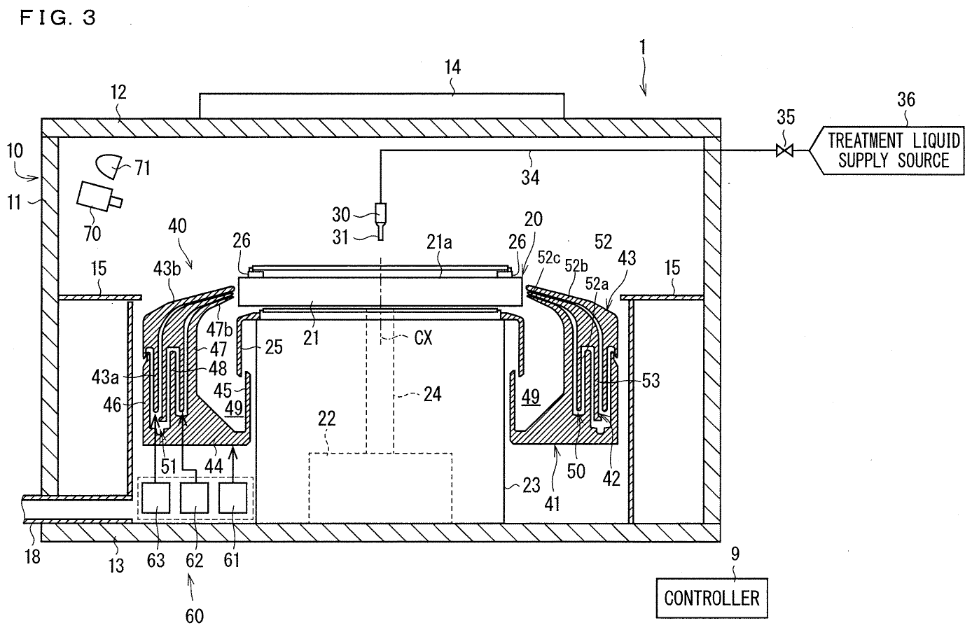

FIG. 2 is a plan view schematically illustrating an example of a configuration of the treatment unit 1. FIG. 3 is a longitudinal sectional view schematically illustrating an example of the configuration of the treatment unit 1.

The treatment unit 1 includes a spin chuck 20 as an example of a substrate holder, a first nozzle 30, a second nozzle 30A, and a third nozzle 30B as examples of liquid nozzles, a guard portion 40, and a camera 70 in a chamber 10.

The chamber 10 includes a side wall 11 along the vertical direction, a ceiling wall 12 that closes the upper side of the space surrounded by the side wall 11, and a floor wall 13 that closes the lower side. A space surrounded by the side wall 11, the ceiling wall 12, and the floor wall 13 is a treatment space. A part of the side wall 11 of the chamber 10 is provided with an inlet and outlet for the main conveyance robot 103 to carry in and out the substrate W and a shutter for opening and closing the inlet and outlet (both are not illustrated).

A fan filter unit (FFU) 14 for further cleaning air in a clean room where the substrate treatment apparatus 100 is installed and supplying the air to the treatment space in the chamber 10 is attached to the ceiling wall 12 of the chamber 10. The fan filter unit 14 includes a fan and a filter (for example, a high efficiency particulate air (HEPA) filter) for taking in air in the clean room and sending the air into the chamber 10, and forms a down flow of clean air in the treatment space in the chamber 10. In order to uniformly disperse the clean air supplied from the fan filter unit 14, a punching plate having a large number of blow-out holes may be provided immediately below the ceiling wall 12.

The spin chuck 20 holds the substrate W in a horizontal posture (posture in which the normal is along the vertical direction). The spin chuck 20 includes a disk-shaped spin base 21 fixed in a horizontal posture to an upper end of a rotation shaft 24 extending along the vertical direction. A spin motor 22 for rotating the rotation shaft 24 is provided below the spin base 21. The spin motor 22 rotates the spin base 21 in a horizontal plane via the rotation shaft 24. In addition, a cylindrical cover member 23 is provided so as to surround the spin motor 22 and the rotation shaft 24.

The outer diameter of the disk-shaped spin base 21 is slightly larger than the diameter of the circular substrate W held by the spin chuck 20. Therefore, the spin base 21 has an upper surface 21a facing the entire lower surface of the substrate W to be held in the vertical direction.

A plurality of (four in the present embodiment) chuck pins 26 are erected on a peripheral edge portion of the upper surface 21a of the spin base 21. The plurality of chuck pins 26 are arranged at equal intervals (at 90° intervals in the case of four chuck pins 26 as in the present embodiment) along the circumference corresponding to the peripheral edge of the circular substrate W. Each of the chuck pins 26 is provided to be drivable between a holding position in contact with the peripheral edge of the substrate W and an open position away from the peripheral edge of the substrate W. The plurality of chuck pins 26 are driven in conjunction with each other by a link mechanism (not illustrated) accommodated in the spin base 21. The spin chuck 20 can hold the substrate W in a horizontal posture close to the upper surface 21a above the spin base 21 by stopping the plurality of chuck pins 26 at the respective contact positions (see FIG. 3), and can release the holding of the substrate W by stopping the plurality of chuck pins 26 at the respective open positions.

The lower end of the cover member 23 covering the spin motor 22 is fixed to the floor wall 13 of the chamber 10, and the upper end reaches immediately below the spin base 21. At the upper end portion of the cover member 23, a flange-shaped member 25 is provided which projects substantially horizontally outward from the cover member 23 and further bends and extends downward. In a state where the spin chuck 20 holds the substrate W by the holding by the plurality of chuck pins 26, the spin motor 22 rotates the rotation shaft 24, so that the substrate W can be rotated about a rotation axis CX along the vertical direction passing through the center of the substrate W. The driving of the spin motor 22 is controlled by the controller 9.

The first nozzle 30 discharges the treatment liquid toward the substrate W and supplies the treatment liquid to the substrate W. In the example of FIG. 2, the first nozzle 30 is configured by attaching the discharge head 31 to the tip of the nozzle arm 32. The base end side of the nozzle arm 32 is fixedly connected to the nozzle base 33. The nozzle base 33 is provided so as to be rotatable about an axis along the vertical direction by a motor (not illustrated). As the nozzle base 33 rotates, the first nozzle 30 moves in an arc shape between a nozzle treatment position and a nozzle standby position in the space above the spin chuck 20 as indicated by an arrow AR34 in FIG. 2. The nozzle treatment position is a position where the first nozzle 30 discharges the treatment liquid onto the substrate W, and is, for example, a position facing the central portion of the substrate W in the vertical direction. The nozzle standby position is a position where the first nozzle 30 does not discharge the treatment liquid onto the substrate W, and is, for example, a position radially outside the peripheral edge of the substrate W. The radial direction here is a radial direction with respect to the rotation axis CX.

As illustrated in FIG. 3, the first nozzle 30 is connected to a treatment liquid supply source 36 via a supply pipe 34. The treatment liquid supply source 36 includes a tank that stores the treatment liquid. The supply pipe 34 is provided with a valve 35. When the valve 35 is opened, the treatment liquid supply source 36 supplies the treatment liquid to the first nozzle 30 through the supply pipe 34, and the treatment liquid is discharged from the discharge port of the first nozzle 30. Note that the first nozzle 30 may be configured to be supplied with a plurality of types of treatment liquids (including at least pure water).

The treatment unit 1 of the present embodiment is further provided with a second nozzle 30A and a third nozzle 30B in addition to the first nozzle 30. The second nozzle 30A and the third nozzle 30B of the present embodiment have the same configuration as the first nozzle 30. That is, the second nozzle 30A is configured by attaching a discharge head 31A to a tip of a nozzle arm 32A. The second nozzle 30A moves in an arc shape in a space above the spin chuck 20 as indicated by an arrow AR64 by a nozzle base 33 A connected to the proximal end side of the nozzle arm 32A. Similarly, the third nozzle 30B is configured by attaching a discharge head 31B to a tip of a nozzle arm 32B. The third nozzle 30B moves in an arc shape in a space above the spin chuck 20 as indicated by an arrow AR69 by a nozzle base 33B connected to the proximal end side of the nozzle arm 32B.

Similarly to the first nozzle 30, each of the second nozzle 30A and the third nozzle 30B is connected to a treatment liquid supply source (not illustrated) via a supply pipe (not illustrated). Each supply pipe is provided with a valve, and supply/stop of the treatment liquid is switched by opening and closing the valve. Note that the number of nozzles provided in the treatment unit 1 is not limited to three, and may be one or more.

In the liquid treatment, the treatment unit 1 causes, for example, the first nozzle 30 to discharge the treatment liquid toward the upper surface of the substrate W while rotating the substrate W by the spin chuck 20. The treatment liquid attached to the upper surface of the substrate W spreads on the upper surface of the substrate W by receiving the centrifugal force accompanying the rotation, and scatters from the peripheral edge of the substrate W. By this liquid treatment, treatment corresponding to the type of the treatment liquid can be performed on the upper surface of the substrate W.

The guard portion 40 is a member for receiving the treatment liquid scattered from the peripheral edge of the substrate W. The guard portion 40 has a tubular shape surrounding the spin chuck 20, and includes, for example, a plurality of guards that can raise and lower independently of each other. In the example of FIG. 3, an inner guard 41, a middle guard 42, and an outer guard 43 are illustrated as the plurality of guards. The guard may also be referred to as a treatment cup.

The inner guard 41 surrounds the spin chuck 20 and has a shape that is substantially rotationally symmetric with respect to the rotation axis CX passing through the center of the substrate W held by the spin chuck 20. The inner guard 41 integrally includes a bottom portion 44 having an annular shape in plan view, a cylindrical inner wall portion 45 rising upward from an inner peripheral edge of the bottom portion 44, a cylindrical outer wall portion 46 rising upward from an outer peripheral edge of the bottom portion 44, a first guide portion 47 rising from the bottom portion 44 between the inner wall portion 45 and the outer wall portion 46 and having an upper end portion extending obliquely upward toward a center side (in a direction approaching the rotation axis CX of the substrate W held by the spin chuck 20) while drawing a smooth arc, and a cylindrical middle wall portion 48 rising upward from the bottom portion 44 between the first guide portion 47 and the outer wall portion 46.

The inner wall portion 45 is formed to have a length such that the inner wall portion 45 is accommodated while maintaining an appropriate gap between the cover member 23 and the flange-shaped member 25 in a state where the inner guard 41 is raised the most. The middle wall portion 48 is formed to have a length such that the middle wall portion 48 is accommodated while maintaining an appropriate gap between a second guide portion 52 to be described later of the middle guard 42 and a treatment liquid separation wall 53 in a state where the inner guard 41 and the middle guard 42 are closest to each other.

The first guide portion 47 has an upper end portion 47b extending obliquely upward on the center side (direction approaching the rotation axis CX of the substrate W) while drawing a smooth arc. In addition, a disposal groove 49 for collecting and disposing the used treatment liquid is formed between the inner wall portion 45 and the first guide portion 47. An annular inner collection groove 50 for collecting and recovering the used treatment liquid is formed between the first guide portion 47 and the middle wall portion 48. Furthermore, an annular outer collection groove 51 for collecting and recovering a treatment liquid different in type from the inner collection groove 50 is formed between the middle wall portion 48 and the outer wall portion 46.

An exhaust liquid mechanism (not illustrated) for discharging the treatment liquid collected in the disposal groove 49 and forcibly exhausting the inside of the disposal groove 49 is connected to the disposal groove 49. For example, four exhaust liquid mechanisms are provided at equal intervals along the circumferential direction of the disposal groove 49. A collection mechanism (not illustrated) for collecting the treatment liquid collected in each of the inner collection groove 50 and the outer collection groove 51 to a collection tank provided outside the treatment unit 1 is connected to the inner collection groove 50 and the outer collection groove 51. The bottom portions of the inner collection groove 50 and the outer collection groove 51 are inclined by a minute angle with respect to the horizontal direction, and the collection mechanism is connected to the lowest position thereof. As a result, the treatment liquid flowing into the inner collection groove 50 and the outer collection groove 51 is smoothly collected.

The middle guard 42 surrounds the spin chuck 20 and has a shape that is substantially rotationally symmetric with respect to the rotation axis CX passing through the center of the substrate W held by the spin chuck 20. The middle guard 42 integrally includes a second guide portion 52 and a cylindrical treatment liquid separation wall 53 connected to the second guide portion 52.

The second guide portion 52 has, outside the first guide portion 47 of the inner guard 41, a lower end portion 52a coaxial with the lower end portion of the first guide portion 47, and an upper end portion 52b extending obliquely upward from the center side (direction approaching the rotation axis CX of the substrate W) while drawing a smooth arc from the upper end of the lower end portion 52a. The lower end portion 52a is accommodated in the inner collection groove 50 while maintaining an appropriate gap between the first guide portion 47 and the middle wall portion 48 in a state where the inner guard 41 and the middle guard 42 are closest to each other. The upper end portion 52b is provided so as to vertically overlap with the upper end portion 47b of the first guide portion 47 of the inner guard 41, and in a state where the inner guard 41 and the middle guard 42 are closest to each other, the upper end portion 52b is close to the upper end portion 47b of the first guide portion 47 with a very small interval. Although different from FIG. 3, a folded portion formed by folding the tip portion of the upper end portion 52b downward may be provided. The folded portion has such a length that the folded portion overlaps with the tip of the upper end portion 47b of the first guide portion 47 in the horizontal direction in a state where the inner guard 41 and the middle guard 42 are closest to each other.

The upper end portion 52b of the second guide portion 52 is formed so as to be thicker toward the lower side, and the treatment liquid separation wall 53 has a cylindrical shape provided so as to extend downward from the lower end outer peripheral edge portion of the upper end portion 52b. The treatment liquid separation wall 53 is accommodated in the outer collection groove 51 while maintaining an appropriate gap between the middle wall portion 48 and the outer guard 43 in a state where the inner guard 41 and the middle guard 42 are closest to each other.

The outer guard 43 surrounds the spin chuck 20 outside the second guide portion 52 of the middle guard 42, and has a shape that is substantially rotationally symmetric with respect to the rotation axis CX passing through the center of the substrate W held by the spin chuck 20. The outer guard 43 has a function as a third guide portion. The outer guard 43 has a lower end portion 43a that is coaxial with the lower end portion 52a of the second guide portion 52, and an upper end portion 43b that extends obliquely upward toward the center side (direction approaching the rotation axis CX of the substrate W) while drawing a smooth arc from the upper end of the lower end portion 43a.

The lower end portion 43a is accommodated in the outer collection groove 51 while maintaining an appropriate gap between the treatment liquid separation wall 53 of the middle guard 42 and the outer wall portion 46 of the inner guard 41 in a state where the inner guard 41 and the outer guard 43 are closest to each other. The upper end portion 43b is provided so as to vertically overlap with the second guide portion 52 of the middle guard 42, and in a state where the middle guard 42 and the outer guard 43 are closest to each other, the upper end portion 43b is close to the upper end portion 52b of the second guide portion 52 with a very small interval. Although different from FIG. 3, a folded portion formed by folding the tip portion of the upper end portion 43b downward may be provided. The folded portion is formed so as to horizontally overlap with the folded portion of the second guide portion 52 in a state where the middle guard 42 and the outer guard 43 are closest to each other.

The inner guard 41, the middle guard 42, and the outer guard 43 can be raised and lowered by a guard raising and lowering mechanism 61, a guard raising and lowering mechanism 62, and a guard raising and lowering mechanism 63, respectively. Hereinafter, the guard raising and lowering mechanisms 61 to 63 may be collectively referred to as a guard raising and lowering mechanism 60.

The guard raising and lowering mechanism 60 raises and lowers the inner guard 41, the middle guard 42, and the outer guard 43 between their guard treatment positions and guard standby positions so as not to collide with each other. The guard treatment position is a position where the upper end peripheral edge portion of the target guard to be raised and lowered is above the upper surface of the substrate W, and the guard standby position is a position where the upper end peripheral edge portion of the target guard is below the upper surface 21a of the spin base 21. Here, the upper end peripheral edge portion is an annular portion that forms an upper end opening of the target guard. In the example of FIG. 3, the inner guard 41, the middle guard 42, and the outer guard 43 are located at the guard standby positions.

The partition plate 15 is provided to vertically partition the inner space of the chamber 10 around the guard portion 40. A through hole or a notch penetrating in the thickness direction may be formed in the partition plate 15, and in the present embodiment, through holes for passing support shafts for supporting the nozzle base 33 of the first nozzle 30, the nozzle base 33A of the second nozzle 30A, and the nozzle base 33B of the third nozzle 30B are formed. An outer peripheral end of the partition plate 15 is connected to the side wall 11 of the chamber 10. An end edge portion surrounding the guard portion 40 of the partition plate 15 is formed in a circular shape having a diameter larger than the outer diameter of the outer guard 43. Therefore, the partition plate 15 does not obstruct the raising and lowering of the outer guard 43.

An exhaust duct 18 is provided in a part of the side wall 11 of the chamber 10 and in the vicinity of the floor wall 13. The exhaust duct 18 is communicably connected to an exhaust mechanism (not illustrated). Of the clean air supplied from the fan filter unit 14 and flowing down in the chamber 10, air that has passed between the guard portion 40 and the partition plate 15 is discharged from the exhaust duct 18 to the outside of the apparatus.

The camera 70 is installed above the substrate W held by the spin chuck 20 in the chamber 10. In the example of FIG. 3, the camera 70 is installed above the partition plate 15. Furthermore, in the example of FIG. 3, the camera 70 is located radially outward with respect to the guard portion 40. The radial direction here is a radial direction with respect to the rotation axis CX.

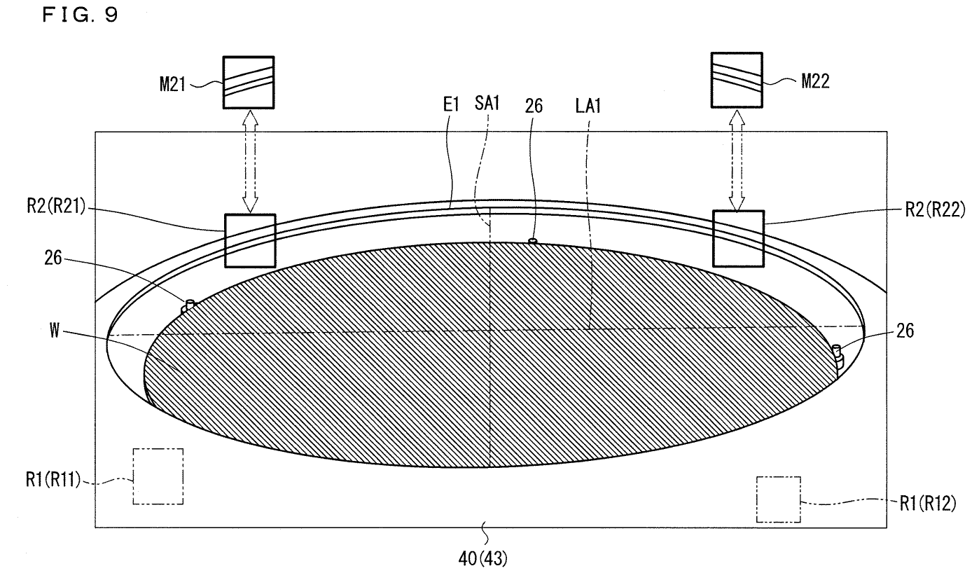

The camera 70 includes a solid-state image capturing element such as a charge coupled device (CCD) or a complementary metal oxide semiconductor (CMOS), and an optical system such as a lens. The camera 70 captures an image of an image capturing region including the guard portion 40 from obliquely above. Here, the image capturing region is set to a region including the entire circumference of the upper end peripheral edge portion of the outer guard 43 in a state where the outer guard 43 is located at the guard treatment position (see also FIG. 9 to be described later). The camera 70 captures an image of the image capturing region to generate captured image data (hereinafter, it is simply referred to as a captured image), and outputs the captured image to the controller 9.

In the example of FIG. 3, an illumination unit 71 is provided at a position above the partition plate 15 in the chamber 10. In a case where the inside of the chamber 10 is a dark room, the controller 9 may control the illumination unit 71 so that the illumination unit 71 emits light when the camera 70 captures an image.

A hardware configuration of the controller 9 is the same as that of a general computer. That is, the controller 9 includes a data processing unit such as a CPU that performs various types of arithmetic processing, a non-temporary storage unit such as a ROM (Read Only Memory) that is a read-only memory for storing a basic program, and a temporary storage unit such as a RAM (Random Access Memory) that is a readable/writable memory for storing various types of information. When the CPU of the controller 9 executes a predetermined processing program, each operation mechanism of the substrate treatment apparatus 100 is controlled by the controller 9, and treatment in the substrate treatment apparatus 100 proceeds. Note that the controller 9 may be realized by a dedicated hardware circuit that does not require software for realizing the function.

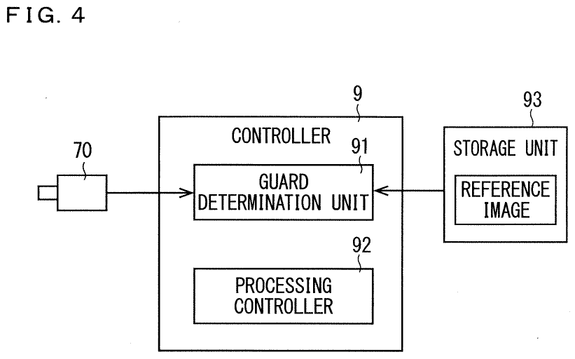

FIG. 4 is a functional block diagram schematically illustrating an example of an internal configuration of the controller 9. As illustrated in FIG. 4, the controller 9 includes a guard determination unit 91 and a processing controller 92.

The processing controller 92 controls each component of the treatment unit 1. Specifically, the processing controller 92 controls various valves such as the spin motor 22 and the valve 35, the motors and the nozzle raising and lowering mechanisms of the nozzle bases 33, 33A, and 33B, the guard raising and lowering mechanisms 61 to 63, the fan filter unit 14, and the camera 70. The processing controller 92 controls these configurations according to a predetermined procedure, so that the treatment unit 1 can perform treatment on the substrate W. An example of a specific flow of treatment for the substrate W will be described in detail later.

The guard determination unit 91 determines the presence or absence of the abnormality related to the position or the shape of the guard portion 40 based on the captured image captured by the camera 70. An example of a specific guard determination method will be described in detail later.

### Example of Flow of Substrate Treatment

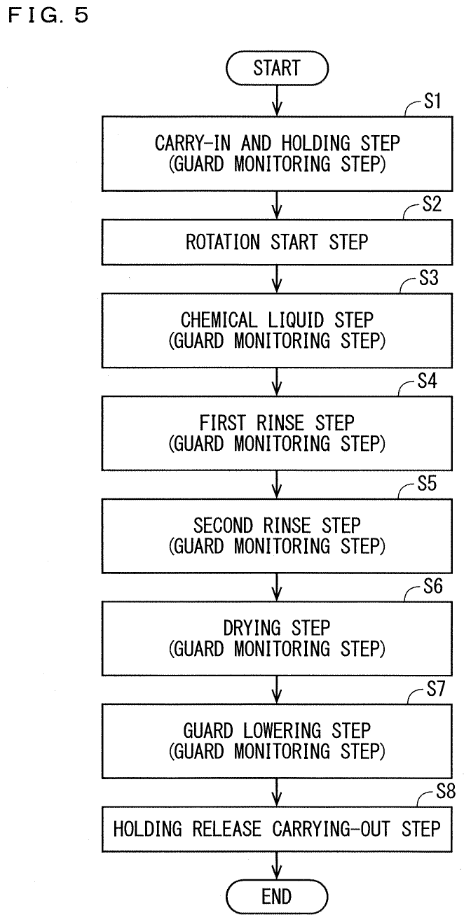

FIG. 5 is a flowchart illustrating an example of a flow of a substrate treatment. Initially, the guard portion 40 stops at the guard standby position. That is, each of the inner guard 41, the middle guard 42, and the outer guard 43 stops at the guard standby position (see FIG. 3). Note that, although the controller 9 controls each configuration to execute a predetermined operation to be described later, each configuration itself will be adopted and described below as a subject of the operation.

First, the main conveyance robot 103 carries the untreated substrate W into the treatment unit 1, and the spin chuck 20 holds the substrate W (step S1: carrying-in and holding step). Since the guard portion 40 initially stops at the guard standby position, collision between the hand of the main conveyance robot 103 and the guard portion 40 can be avoided when the substrate W is carried in. When the substrate W is transferred to the spin chuck 20, the plurality of chuck pins 26 move to the respective contact positions, whereby the plurality of chuck pins 26 hold the substrate W.

Next, the spin motor 22 starts rotation of the substrate W (step S2: rotation start step). Specifically, the spin motor 22 rotates the spin chuck 20 to rotate the substrate W held by the spin chuck 20.

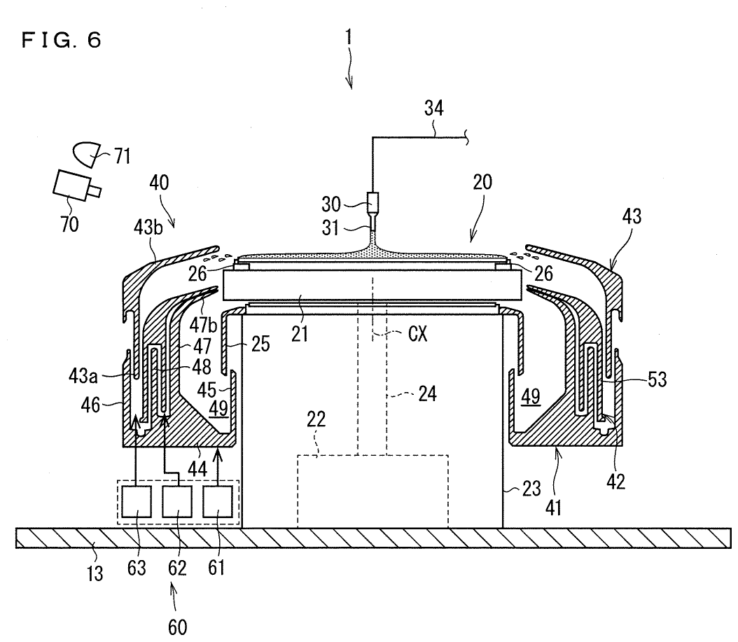

Next, the treatment unit 1 performs various liquid treatments on the substrate W. In the example of FIG. 5, the treatment unit 1 first performs a chemical liquid treatment (step S3: chemical liquid step). FIG. 6 is a view schematically illustrating an example of a state in the treatment unit 1 in the chemical liquid treatment.

First, the guard raising and lowering mechanism 60 raises the guard corresponding to the chemical liquid among the guards 41 to 43 to the guard treatment position. The guard for the chemical liquid is not particularly limited, but may be, for example, the outer guard 43. In this case, the guard raising and lowering mechanism 60 stops the inner guard 41 and the middle guard 42 at the guard standby positions, and raises the outer guard 43 to the guard treatment position (see FIG. 6).

Next, the treatment unit 1 supplies the chemical liquid to the substrate W. Here, it is assumed that the first nozzle 30 supplies the treatment liquid. Specifically, the nozzle base 33 moves the first nozzle 30 to the nozzle treatment position, and the valve 35 is opened to discharge the chemical liquid from the first nozzle 30 toward the substrate W. As a result, the chemical liquid spreads over the upper surface of the rotating substrate W and scatters from the peripheral edge of the substrate W. The scattered chemical liquid is received by the inner peripheral surface of the guard portion 40 (for example, the outer guard 43). When the chemical liquid acts on the upper surface of the substrate W, a treatment (for example, cleaning treatment) corresponding to the chemical liquid is performed on the substrate W. When the chemical liquid treatment is sufficiently performed, the treatment unit 1 stops the supply of the chemical liquid.

Next, the treatment unit 1 performs a first rinse treatment on the substrate W (step S4: first rinse step). The guard raising and lowering mechanism 60 adjusts a raising and lowering state of the guard portion 40 as necessary. That is, when the guard for the first rinse liquid is different from the guard for the chemical liquid, the guard raising and lowering mechanism 60 moves the guard corresponding to the first rinse liquid among the guards 41 to 43 to the guard treatment position. The guard for the first rinse liquid is not particularly limited, but may be the inner guard 41. In this case, the guard raising and lowering mechanism 60 raises the guards 41 to 43 to the respective guard treatment positions.

Next, the first nozzle 30 discharges the first rinse liquid toward the upper surface of the substrate W. The first rinse liquid is, for example, pure water. The first rinse liquid spreads over the upper surface of the rotating substrate W and scatters from the peripheral edge of the substrate W while pushing away the chemical liquid on the substrate W. The treatment liquid (mainly the first rinse liquid) scattered from the peripheral edge of the substrate W is received by the inner peripheral surface of the guard portion 40 (for example, the inner guard 41). When the first rinse treatment is sufficiently performed, the treatment unit 1 stops the supply of the first rinse liquid.

Next, the treatment unit 1 performs a second rinse treatment on the substrate W (step S5: second rinse step). The guard raising and lowering mechanism 60 adjusts a raising and lowering state of the guard portion 40 as necessary. That is, when the guard for the second rinse liquid is different from the guard for the first rinse liquid, the guard raising and lowering mechanism 60 moves the guard corresponding to the second rinse liquid among the guards 41 to 43 to the guard treatment position.

Next, the first nozzle 30 discharges the second rinse liquid toward the upper surface of the substrate W. The second rinse liquid is a liquid having a lower latent heat of vaporization than that of the first rinse liquid, and is, for example, isopropyl alcohol. The second rinse liquid spreads over the upper surface of the substrate W and scatters from the peripheral edge of the substrate W while pushing away the first rinse liquid on the substrate W. The treatment liquid (mainly the second rinse liquid) scattered from the peripheral edge of the substrate W is received by the inner peripheral surface of the guard portion 40. When the second rinse treatment is sufficiently performed, the treatment unit 1 stops the supply of the second rinse liquid and moves the first nozzle 30 to the nozzle standby position.

Next, the treatment unit 1 performs drying treatment on the substrate W (step S6: drying step). For example, the spin motor 22 increases the rotation speed of the substrate W to dry the substrate W (so-called spin dry). Also in the drying treatment, the treatment liquid scattered from the peripheral edge of the substrate W is received by the inner peripheral surface of the guard portion 40. When the drying treatment is sufficiently performed, the spin motor 22 stops the rotation of the substrate W.

Next, the guard raising and lowering mechanism 60 lowers the guard portion 40 to the guard standby position (step S7: guard lowering step). That is, the guard raising and lowering mechanism 60 lowers the inner guard 41, the middle guard 42, and the outer guard 43 to the respective guard standby positions.

Next, the spin chuck 20 releases the holding of the substrate W, and the main conveyance robot 103 carries out the substrate W from the treatment unit 1 (step S8: holding release carrying-out step). Since the guard portion 40 stops at the guard standby position when the substrate W is carried out, it is possible to avoid collision between the hand of the main conveyance robot 103 and the guard portion 40.

By the above operation, the treatment unit 1 can perform treatment on the substrate W.

### Position of Guard

As is apparent from the operation of the substrate treatment described above, the guard portion 40 moves to a height position corresponding to each step. Specifically, when the substrate W is carried in and out (steps S1 and S8), the guard portion 40 stops at the guard standby position. Accordingly, collision between the hand of the main conveyance robot 103 and the guard portion 40 can be avoided. In addition, when various treatment liquids are supplied to the substrate W (steps S3 to S5), the elevated state of the guard portion 40 becomes a state corresponding to the type of the treatment liquid. Therefore, the treatment liquid can be received by the guard corresponding to the type of the treatment liquid in the guard portion 40, and the treatment liquid can be appropriately recovered or discarded.

However, if the guard portion 40 cannot move to an appropriate height position corresponding to each step, a problem may occur. For example, if the guard portion 40 does not stop at the guard standby position when the substrate W is carried in and out, the hand of the main conveyance robot 103 may collide with the guard portion 40. When the guard corresponding to the type of the treatment liquid does not stop at the guard treatment position at the time of supplying the treatment liquid, the treatment liquid is not appropriately recovered or discarded.

### Guard Monitoring Processing

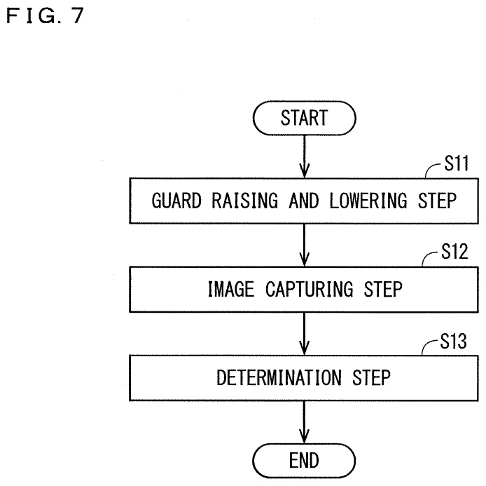

Therefore, in the present embodiment, the treatment unit 1 performs guard monitoring processing on the guard portion 40. FIG. 7 is a flowchart illustrating an example of guard monitoring processing according to the first embodiment. Hereinafter, an example of the guard monitoring processing will be first outlined, and then an example of the guard monitoring processing will be described in detail by roughly classifying the state in which the guard portion 40 stops at the guard standby position and the state in which the guard portion 40 stops at the guard treatment position.

As illustrated in FIG. 7, first, the guard raising and lowering mechanism 60 moves the guard portion 40 to a predetermined height position (target height position) (step S11: guard raising and lowering step). The guard raising and lowering step corresponds to movement of the guard portion 40 performed in each of the chemical liquid step (step S3), the first rinse step (step S4), the second rinse step (step S5), and the guard lowering step (step S7) described above.

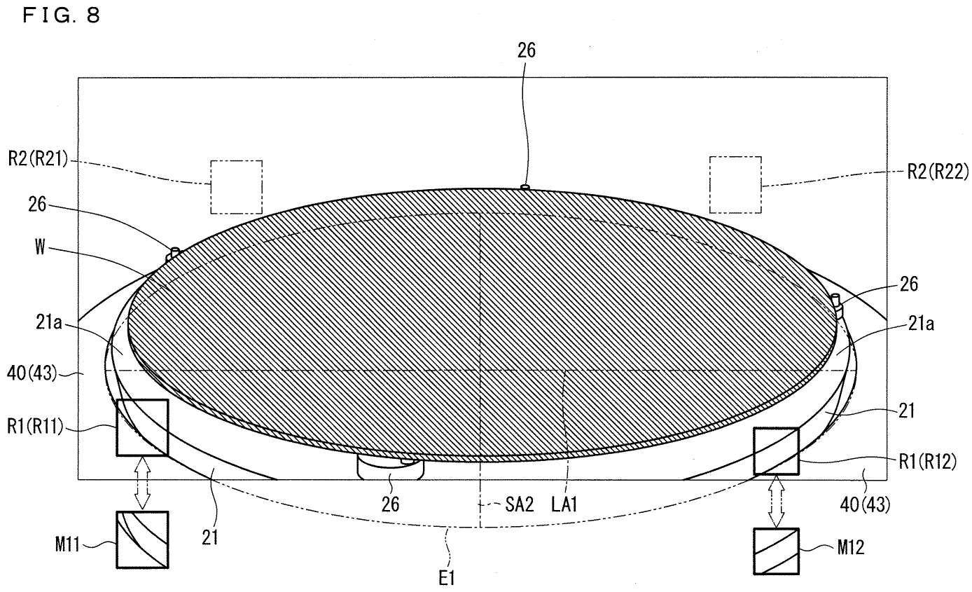

Next, the camera 70 captures an image of the image capturing region including the guard portion 40 to generate a captured image, and outputs the captured image to the controller 9 (step S12: image capturing step). FIGS. 8 and 9 are views schematically illustrating an example of the captured images. FIG. 8 illustrates a captured image captured when the guards 41 to 43 of the guard portion 40 stop at the respective guard standby positions, and FIG. 9 illustrates a captured image captured when only the outer guard 43 of the guard portion 40 stops at the guard treatment position. When the guard portion 40 moves to the guard standby position in the guard raising and lowering step, the captured image illustrated in FIG. 8 is generated in the image capturing step, and when only the outer guard 43 of the guard portion 40 moves to the guard treatment position in the guard raising and lowering step, the captured image illustrated in FIG. 9 is generated in the image capturing step.

Next, the guard determination unit 91 of the controller 9 determines the presence or absence of the abnormality related to the guard portion 40 based on the pixel value in the captured image (step S13: determination step). Here, a normal captured image when the guard portion 40 is normally located at a predetermined height position is stored in a nonvolatile non-transitory storage unit (for example, a memory) 93 as reference image data (hereinafter, simply referred to as a reference image). Then, the guard determination unit 91 determines the presence or absence of the abnormality related to the guard portion 40 based on the comparison between the captured image and the reference image.

### Guard Standby Position

Here, a case where the guard portion 40 moves to the guard standby position in the guard raising and lowering step (step S11) will be described in detail. Specifically, a case where the guard raising and lowering step corresponds to the movement of the guard portion 40 performed in the guard lowering step (step S7) will be described in detail.

First, in the guard raising and lowering step, the processing controller 92 of the controller 9 outputs control signals to the guard raising and lowering mechanisms 61 to 63. These control signals are signals for moving the guards 41 to 43 to the respective guard standby positions. The guard raising and lowering mechanisms 61 to 63 move the guards 41 to 43 to the respective guard standby positions in response to the control signal.

At this time, if the guard raising and lowering mechanism 60 can normally move the guard portion 40 to the guard standby position, it is possible to avoid collision between the hand of the main conveyance robot 103 and the guard portion 40 in the next holding release carrying-out step (step S8). On the other hand, if the guard portion 40 cannot be normally moved to the guard standby position due to a factor such as an abnormality of the guard raising and lowering mechanism 60, the hand of the transfer robot may collide with the guard portion 40.

Therefore, the treatment unit 1 sequentially performs the image capturing step (step S12) and the determination step (step S13) before the main conveyance robot 103 starts to move the hand (that is, before carrying-out processing). Note that the substantial guard monitoring processing is realized by the image capturing step and the determination step.

In the image capturing step, the captured image illustrated in FIG. 8 is generated. In the example of FIG. 8, the captured image includes the entire upper surface of the treated substrate W and a part of the outer guard 43 that stops at the guard standby position. In the example of FIG. 8, only the outer guard 43 of the guard portion 40 is included in the captured image, and the inner guard 41 and the middle guard 42 are not included.

Here, the guard determination unit 91 determines the presence or absence of an abnormality related to the outer guard 43 based on the captured image. This is because collision between the hand of the main conveyance robot 103 and the guard portion 40 can be avoided when the outer guard 43 located at the highest position is normally located at the guard treatment position. That is, the guard determination unit 91 only needs to be able to determine the presence or absence of the abnormality related to the outer guard 43, and the captured image may not include the inner guard 41 and the middle guard 42.

The guard determination unit 91 determines the presence or absence of the abnormality related to the outer guard 43 based on the comparison between the captured image and the reference image for the standby position. The reference image for the standby position is a normal captured image captured by the camera 70 when the outer guard 43 normally stops at the guard standby position, and is stored in advance in the storage unit 93.

In the example of FIG. 8, at least one determination region R1 is set in the captured image. The determination region R1 is set to a region including a part of the outer guard 43 (specifically, a part of the upper end peripheral edge portion) when the outer guard 43 is normally located at the guard standby position. In the example of FIG. 8, the determination region R1 is set to a region including a peripheral edge portion on the front side as viewed from the camera 70 in the upper end peripheral edge portion of the outer guard 43. In other words, the determination region R1 is set to a portion below a major axis LA1 of a virtual ellipse E1 along which the upper end peripheral edge portion of the outer guard 43 extends in the captured image.

In the example of FIG. 8, the determination region R1 is set to a region not including the substrate W. Since the interval between the peripheral edge of the substrate W and the upper end peripheral edge portion of the outer guard 43 is wider below the major axis LA1 of the ellipse E1, when the determination region R1 is set below the major axis LA1, it is easy to set the determination region R1 in a region not including the substrate W and including the upper end peripheral edge portion of the outer guard 43.

In the example of FIG. 8, a first determination region R11 and a second determination region R12 are set as the determination region R1. The first determination region R11 and the second determination region R12 are set on opposite sides to each other with respect to the minor axis SA1 of the ellipse E1.

As the reference image for the standby position, a first reference image M11 in the same region as the first determination region R11 and a second reference image M12 in the same region as the second determination region R12 are stored in advance in the storage unit 93.

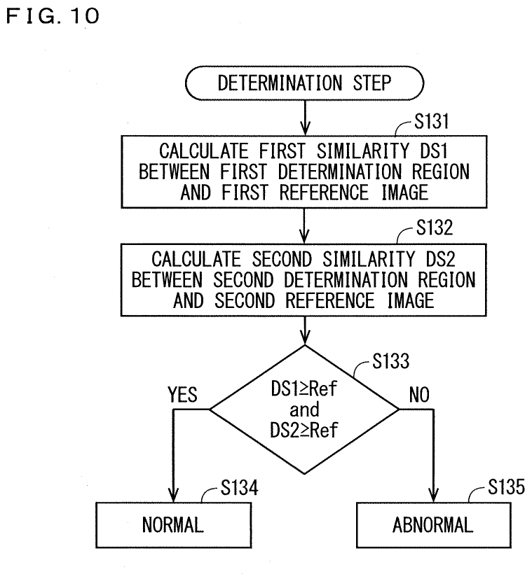

FIG. 10 is a flowchart illustrating an example of a more specific operation of the determination step (step S13). First, the guard determination unit 91 calculates similarity (hereinafter, referred to as first similarity) DS1 between the first determination region R11 and the first reference image M11 based on the pixel value in the first determination region R11 and the pixel value in the first reference image M11 (step S131). The similarity is not particularly limited, but may be, for example, a known similarity such as a sum of squared differences of pixel values, a sum of absolute differences of pixel values, normalized cross-correlation, or zero-mean normalized cross-correlation. When the similarity is normalized cross-correlation or 0 average normalized cross-correlation, the similarity takes a value between −1.0 and 1.0 inclusive.

Next, the guard determination unit 91 calculates similarity (hereinafter, also referred to as second similarity) DS2 between the second determination region R12 and the second reference image M12 based on the pixel value in the second determination region R12 and the pixel value in the second reference image M12 (step S132). If these similarities are high, it is considered that the outer guard 43 normally stops at the guard standby position.

Next, the guard determination unit 91 determines whether both the first similarity DS1 and the second similarity DS2 are equal to or greater than a prescribed threshold Ref (step S133). That is, the guard determination unit 91 determines whether or not it is provisionally determined that the outer guard 43 normally stops at the guard standby position in both the provisional determination result based on the pixel value in the first determination region R11 and the provisional determination result based on the pixel value in the second determination region R12.

When both the first similarity DS1 and the second similarity DS2 are equal to or greater than the threshold Ref, the guard determination unit 91 determines that the outer guard 43 normally stops at the guard standby position (step S134). That is, when temporarily determining that the outer guard 43 is normal in both the first determination region R11 and the second determination region R12, the guard determination unit 91 determines that the outer guard 43 is normal.

On the other hand, when at least one of the first similarity DS1 and the second similarity DS2 is less than the threshold Ref, the guard determination unit 91 determines that an abnormality has occurred in the outer guard 43 (step S135). That is, the guard determination unit 91 determines that the outer guard 43 is not normally located at the guard standby position. When the guard determination unit 91 detects an abnormality, the treatment unit 1 may interrupt the treatment, and a notification unit (for example, a display) (not illustrated) may notify the user of the occurrence of the abnormality.

As described above, the abnormality related to the outer guard 43 can be detected by the guard monitoring processing. When an abnormality is detected, the main conveyance robot 103 can stop the start of the carrying-out processing of the substrate W. Accordingly, collision between the hand of the main conveyance robot 103 and the guard portion 40 can be avoided.

Although the guard monitoring processing before the substrate W is carried out has been described above, the treatment unit 1 may also perform the same guard monitoring processing before the substrate W is carried in. That is, the treatment unit 1 may perform the image capturing step (step S12) and the determination step (step S13) even immediately before the substrate W is carried in the holding and carrying-in step (step S1). Even when an abnormality is detected in the determination step immediately before the carrying-in of the substrate W, the main conveyance robot 103 can stop the start of the carrying-in processing of the substrate W. Accordingly, collision between the hand of the main conveyance robot 103 and the guard portion 40 can be avoided.

In the present exemplary embodiment, as described above, the guard determination unit 91 directly determines the presence or absence of the abnormality based on the captured image including the guard portion 40. Therefore, even if an abnormality such as step-out has occurred in the guard raising and lowering mechanism 60, the abnormality of the outer guard 43 can be appropriately determined. That is, the guard determination unit 91 can determine the presence or absence of the abnormality with higher accuracy.

In the example of FIG. 8, the determination region R1 is set in only a partial region of the captured image, and the guard determination unit 91 determines the presence or absence of the abnormality based on the pixel value in the determination region R1. Conversely, the configuration included in the region other than the determination region R1 in the captured image is not used for the determination. Therefore, the guard determination unit 91 can avoid the influence of the configuration on the determination result, and can determine the presence or absence of the abnormality with higher determination accuracy.

In the example of FIG. 8, the determination region R1 is set to a region that does not include the substrate W in the captured image. By the way, since the spin chuck 20 does not yet hold the substrate W before the substrate W is carried into the treatment unit 1, the substrate W is naturally not included in the captured image captured at this time. On the other hand, since the spin chuck 20 holds the substrate W before the substrate W is carried out from the treatment unit 1, the substrate W is included in the captured image captured at this time as illustrated in FIG. 8. As described above, both captured images are different from each other in the presence or absence of the substrate W.

However, since the substrate W is not included in the determination region R1 set in the captured image, the presence or absence of such a substrate W does not affect the determination. Therefore, even when the common determination region R1 and the common reference image for the standby position are used at the time of carrying in and out the substrate W, the guard determination unit 91 can appropriately determine the presence or absence of the abnormality.

In the example of FIG. 8, the first determination region R11 and the second determination region R12 are set as the determination region R1. When temporarily determining that the outer guard 43 is normal in both the first determination region R11 and the second determination region R12, the guard determination unit 91 determines that the outer guard 43 is normal.

For comparison, a case where the presence or absence of the abnormality of the outer guard 43 is determined only in the first determination region R11 will be described. In this case, when the guard portion 40 is inclined due to a factor such as an abnormality of the guard raising and lowering mechanism 60, erroneous determination may be caused. For example, when the guard raising and lowering mechanism 63 raises and lowers the lower end of the outer guard 43 by supporting the lower end at a plurality of positions, the outer guard 43 is inclined when a failure occurs at one position. In this case, the upper end peripheral edge portion of the outer guard 43 is inclined with respect to the horizontal plane.

When the outer guard 43 is inclined in this manner, the second determination region R12 may deviate from the second reference image M12 although the first determination region R11 is similar to the first reference image M11. In this case, when the guard determination unit 91 determines the presence or absence of the abnormality only in the first determination region R11, it can be erroneously determined that the outer guard 43 is normal. That is, abnormality detection omission occurs.

On the other hand, if the guard determination unit 91 determines the presence or absence of the abnormality using both the first determination region R11 and the second determination region R12, such erroneous determination can be suppressed. In other words, the guard determination unit 91 can determine the presence or absence of the abnormality with higher determination accuracy.

Moreover, in the example of FIG. 8, the first determination region R11 and the second determination region R12 are set on the opposite sides to each other with respect to the minor axis SA1 of the virtual ellipse E1. Therefore, the guard determination unit 91 can easily detect an abnormality caused by the inclination of the outer guard 43.

### Guard Treatment Position

Next, a case where the guard portion 40 moves to the guard treatment position in the guard raising and lowering step (step S11) will be described in detail. That is, a case where the guard raising and lowering step corresponds to the movement of the guard portion 40 performed in any one of the chemical liquid step (step S3), the first rinse step (step S4), and the second rinse step (step S5) will be described in detail.

First, in the guard raising and lowering step, the guard raising and lowering mechanism 60 appropriately moves the guards 41 to 43 according to the type of the treatment liquid as described above. Here, it is assumed that only the outer guard 43 raises to the guard treatment position. That is, the processing controller 92 of the controller 9 outputs a control signal for raising only the outer guard 43 to the guard treatment position to the guard raising and lowering mechanisms 61 to 63. The guard raising and lowering mechanism 60 appropriately moves the guards 41 to 43 according to the control signal.

If the guard raising and lowering mechanism 60 can normally move the guards 41 to 43, the treatment liquid scattered from the peripheral edge of the substrate W is received by an appropriate guard at the time of supplying the next treatment liquid, and is recovered or discarded. On the other hand, if the guards 41 to 43 cannot move normally due to a factor such as an abnormality of the guard raising and lowering mechanism 60, the treatment liquid cannot be appropriately received by an appropriate guard.

Therefore, the treatment unit 1 performs the image capturing step (step S12) and the determination step (step S13) before supplying the next treatment liquid. For example, in the chemical liquid treatment, the treatment unit 1 performs an image capturing step and a determination step before supplying the chemical liquid to the substrate W.

In the image capturing step, the captured image illustrated in FIG. 9 is generated. In the example of FIG. 9, the captured image includes the entire upper end peripheral edge portion of the outer guard 43 that stops at the guard treatment position. In the example of FIG. 9, the upper surface of the substrate W is also included in the captured image, but the peripheral edge portion on the front side is blocked by the outer guard 43. Therefore, in the captured image of FIG. 9, the peripheral edge portion on the front side of the upper end peripheral edge portion of the guard portion 40 is continuous with the substrate W in the vertical direction.

The guard determination unit 91 determines the presence or absence of the abnormality related to the guard portion 40 (here, the outer guard 43) based on the captured image and the reference image for the treatment position. The reference image for the treatment position is a normal captured image captured by the camera 70 when the guard portion 40 (here, only the outer guard 43) normally stops at the guard treatment position, and is stored in advance in the storage unit 93.

In the example of FIG. 9, at least one determination region R2 is set in the captured image. The determination region R2 is set to a region including a part of the upper end peripheral edge portion of the outer guard 43 when the outer guard 43 is normally located at the guard treatment positions. In the example of FIG. 9, the determination region R2 is set to a region including a peripheral edge portion on the back side as viewed from the camera 70 in the upper end peripheral edge portion of the outer guard 43. In other words, the determination region R2 is set to a portion above the major axis LA1 of the virtual ellipse E1 along which the upper end peripheral edge portion of the outer guard 43 extends in the captured image.

In the example of FIG. 9, the determination region R2 is set to a region not including the substrate W. Since the interval between the peripheral edge of the substrate W and the upper end peripheral edge portion of the outer guard 43 is wider on the upper side than the major axis LA1 of the ellipse E1, when the determination region R2 is set above the major axis LA1, it is easy to set the determination region R2 in a region not including the substrate W and including the upper end peripheral edge portion of the outer guard 43.

In the example of FIG. 9, a first determination region R21 and a second determination region R22 are set as the determination region R2. The first determination region R21 and the second determination region R22 are set on opposite sides to each other with respect to the minor axis SA1 of the ellipse E1.

As the reference image for the treatment position, a first reference image M21 in the same region as the first determination region R21 and a second reference image M22 in the same region as the second determination region R22 are stored in advance in the storage unit 93.

An example of a specific operation of the determination step (step S13) is similar to the flowchart of FIG. 10. First, the guard determination unit 91 calculates the first similarity DS1 between the first determination region R21 and the first reference image M21 based on the pixel value in the first determination region R21 and the pixel value in the first reference image M21 (step S131). Next, the guard determination unit 91 calculates the second similarity DS2 between the second determination region R22 and the second reference image M22 based on the pixel value in the second determination region R22 and the pixel value in the second reference image M22 (step S132).

Next, the guard determination unit 91 determines whether both the first similarity DS1 and the second similarity DS2 are equal to or greater than a prescribed threshold Ref (step S133). When both the first similarity DS1 and the second similarity DS2 are equal to or greater than the threshold Ref, the guard determination unit 91 determines that the outer guard 43 is normally located at the guard treatment position (step S134). When at least one of the first similarity DS1 and the second similarity DS2 is less than the threshold Ref, the guard determination unit 91 determines that an abnormality related to the outer guard 43 has occurred (step S135). When the guard determination unit 91 detects an abnormality, the treatment unit 1 may interrupt the treatment, and a notification unit (for example, a display) (not illustrated) may notify the user of the occurrence of the abnormality.

As described above, the abnormality related to the guard portion 40 can be detected by the guard monitoring processing. When an abnormality is detected by the guard monitoring processing, the treatment unit 1 can stop the start of supply of the next treatment liquid. As a result, it is possible to suppress the next treatment liquid from being received by another guard, and it is possible to suppress mixing of the treatment liquid in a collection line or a drainage line.

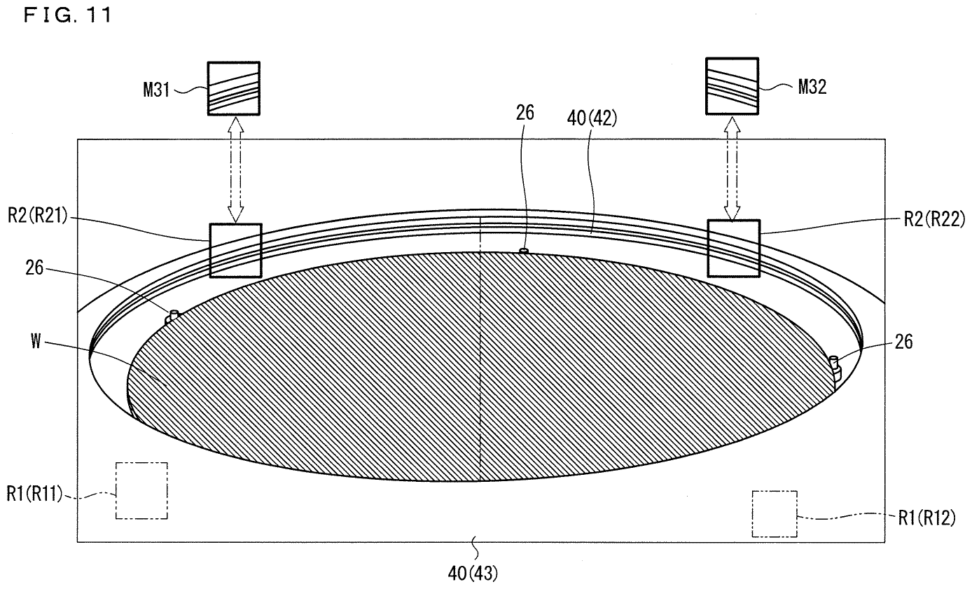

In the specific example described above, the case where only the outer guard 43 stops at the guard treatment position has been described, but the same applies to the case where the inner guard 41 or the middle guard 42 stops at the guard treatment position. FIG. 11 is a view schematically illustrating an example of captured images when the middle guard 42 and the outer guard 43 stop at the respective guard treatment positions. This captured image also includes a part of the middle guard 42 that stops at the guard treatment position. Specifically, a peripheral edge portion of the upper end peripheral edge portion of the middle guard 42 on the back side as viewed from the camera 70 appears immediately below the upper end peripheral edge portion of the outer guard 43 in the captured image. The determination region R2 is set to a region including both the upper end peripheral edge portion of the outer guard 43 and the upper end peripheral edge portion of the middle guard 42 when the guards 42 and 43 are normally located at the guard treatment positions. In the example of FIG. 11, each of the first determination region R21 and the second determination region R22 includes both a part of the upper end peripheral edge portion of the outer guard 43 and a part of the upper end peripheral edge of the middle guard 42.

As the reference image for the treatment position in this case, a normal captured image including the outer guard 43 and the middle guard 42 that normally stop at the guard treatment positions is adopted. In the example of FIG. 11, a first reference image M31 in the same region as the first determination region R21 and a second reference image M32 in the same region as the second determination region R22 are illustrated, and these are stored in advance in the storage unit 93. Each of the first reference image M31 and the second reference image M32 includes both a part of the upper end peripheral edge portion of the outer guard 43 and a part of the upper end peripheral edge portion of the middle guard 42 that normally stop at the guard treatment positions.

The specific operation in the determination step (step S13) is similar to that in FIG. 10. However, the first reference image M31 is used instead of the first reference image M21, and the second reference image M32 is used instead of the second reference image M22.

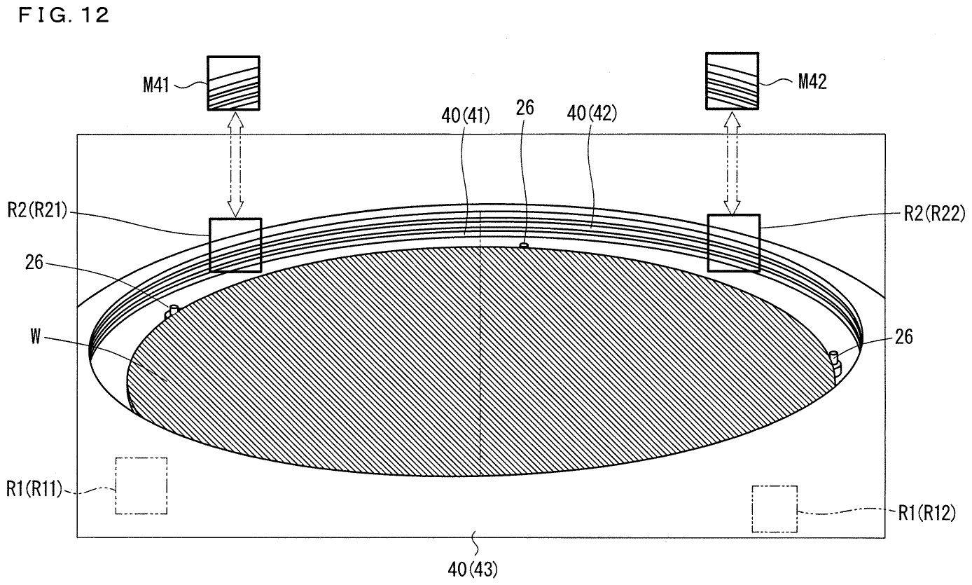

The same applies to a case where the inner guard 41, the middle guard 42, and the outer guard 43 stop at the respective guard treatment positions. FIG. 12 is a view schematically illustrating an example of captured images when the inner guard 41, the middle guard 42, and the outer guard 43 stop at the respective guard treatment positions. The determination region R2 (first determination region R21 and second determination region R22) is set to a region including a part of the upper end peripheral edge portion of each of the guards 41 to 43 when the guards 41 to 43 are normally located at the guard treatment positions. As a first reference image M41 and a second reference image M42 for the treatment position, normal captured images including a part of the upper end peripheral edge portion of each of the guards 41 to 43 that normally stop at the guard treatment positions are adopted, and these are stored in advance in the storage unit 93.

The specific operation in the determination step (step S13) is similar to that in FIG. 10. However, the first reference image M41 is used instead of the first reference image M21, and the second reference image M42 is used instead of the second reference image M22.

As described above, the determination region R2 is preferably set to a region including a part of the upper end peripheral edge portion of each of the guards 41 to 43 when the guards 41 to 43 are normally located at the guard treatment positions. Accordingly, the guard determination unit 91 can determine the presence or absence of the abnormality using the common determination region R2 in a state where at least one of the guards 41 to 43 stops at the guard treatment position (FIGS. 9, 11 and 12).

As described above, the guard determination unit 91 directly detects the abnormality related to the guard portion 40 based on the captured image including the guard portion 40 captured by the camera 70. Therefore, even if an abnormality such as step-out has occurred in the guard raising and lowering mechanism 60, the abnormality of the guard portion 40 can be determined with high accuracy.

In the above example, the determination region R2 is set in only a partial region of the captured image, and the guard determination unit 91 determines the presence or absence of the abnormality based on the pixel value in the determination region R2. Therefore, it is possible to avoid the influence on the determination by the configuration other than the determination region R2, and the guard determination unit 91 can determine the presence or absence of the abnormality with higher determination accuracy.

In the above example, the determination region R2 is set to a region that does not include the substrate W in the captured image. Incidentally, the guard portion 40 may move to the guard treatment position not only during liquid treatment on the substrate W but also during cleaning treatment (hereinafter, referred to as a chamber cleaning treatment) in the chamber 10, for example. For example, when the inner peripheral surface of each of the guards 41 to 43 is cleaned, the guards 41 to 43 appropriately raise to the guard treatment positions. Even in such a case, the treatment unit 1 desirably performs the guard monitoring processing. Such chamber cleaning treatment may be performed without carrying the substrate W into the treatment unit 1. In this case, the captured image naturally does not include the substrate W. On the other hand, in the guard monitoring processing in the liquid treatment, as illustrated in FIGS. 9, 11, and 12, the captured image includes the substrate W. As described above, the captured images in the liquid treatment and the chamber cleaning treatment are different from each other in the presence or absence of the substrate W.

However, since the substrate W is not included in the determination region R2 set in the captured image, the presence or absence of such a substrate W does not affect the determination. Therefore, even when the common determination region R2 and the common reference image for the treatment position are used in each of the liquid treatment and the chamber cleaning treatment, the guard determination unit 91 can appropriately determine the presence or absence of the abnormality related to the guard portion 40.

In the above example, the first determination region R21 and the second determination region R22 are set as the determination region R2. The guard determination unit 91 determines that the guard portion 40 is normal when temporarily determining that the guard portion 40 is normal in both the first determination region R21 and the second determination region R22. Therefore, even when the guard portion 40 is inclined due to a factor such as an abnormality of the guard raising and lowering mechanism 60, the guard determination unit 91 can determine the presence or absence of the abnormality with higher determination accuracy. The first determination region R21 and the second determination region R22 are set on opposite sides to each other with respect to the minor axis SA1 of the ellipse E1. Therefore, the guard determination unit 91 can easily detect an abnormality caused by the inclination of the guard portion 40.

In addition, there is a possibility that a predetermined height position (target height position) of the guard portion 40 that moves in each step is appropriately changed by changing a specification or the like. However, according to the present embodiment, by appropriately changing the determination region and the reference image, it is possible to detect the abnormality of the guard portion 40 according to the height position without changing the hardware configuration of the treatment unit 1.

### Threshold Ref

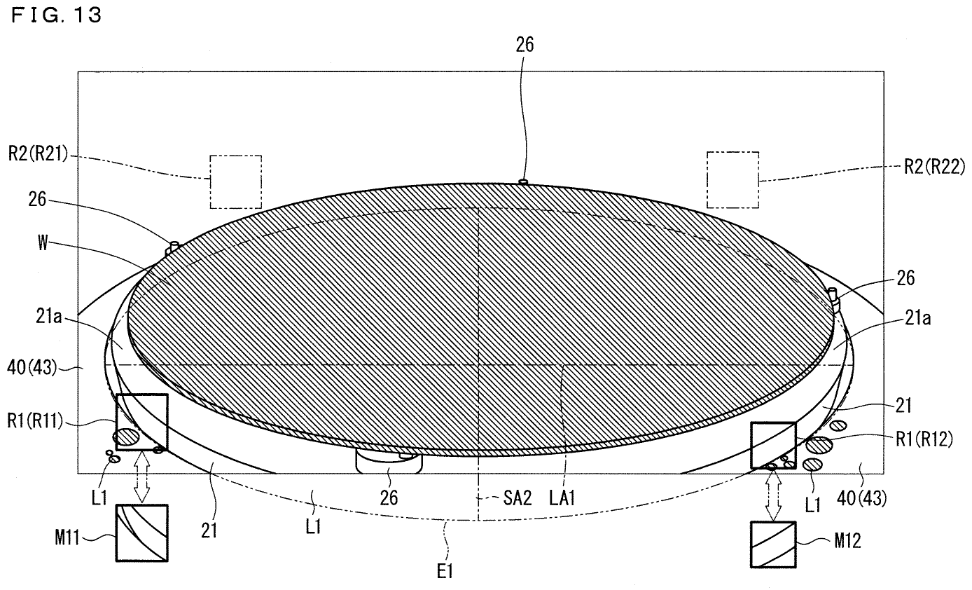

As described above, since the treatment liquid is supplied to the substrate W in the substrate treatment, there is a possibility that the treatment liquid scatters in the chamber 10 and the droplets are attached to the outer peripheral surface of the guard portion 40. In this case, as described in detail below, there is a possibility that the guard determination unit 91 makes an erroneous determination. FIG. 13 is a view schematically illustrating an example of captured images when droplets L1 are attached to the outer peripheral surface of the guard portion 40. In the example of FIG. 13, a plurality of droplets L1 are attached to the outer peripheral surface of the outer guard 43 of the guard portion 40, and the droplets L1 are also included in the first determination region R11 and the second determination region R12. Therefore, the first similarity DS1 between the first determination region R11 and the first reference image M11 and the second similarity DS2 between the second determination region R12 and the second reference image M12 can be lower than the threshold Ref. In this case, although the guard portion 40 normally stops at the guard standby position, the guard determination unit 91 erroneously determines that the guard portion 40 does not normally stop at the guard standby position. That is, the guard determination unit 91 erroneously detects an abnormality related to the guard portion 40.

Therefore, it is contemplated to suppress such erroneous detection by setting the determination region R1. Specifically, the determination region R1 may be set such that the guard area occupied by the outer guard 43 in the determination region R1 becomes small. For example, in the example of FIG. 13, the outline of the first determination region R11 has a rectangular shape including a lower side, a right side, a left side, and an upper side, and the first determination region R11 is set such that the upper end peripheral edge portion of the outer guard 43 intersects the lower side and the right side. Accordingly, the guard area can be reduced as compared with the case where the upper end peripheral edge portion of the outer guard 43 intersects both sides of the first determination region R11. Therefore, since the ratio of the droplets L1 in the determination region R1 can be reduced, the influence of the droplets L1 on the determination can be suppressed. The same applies to the second determination region R12.

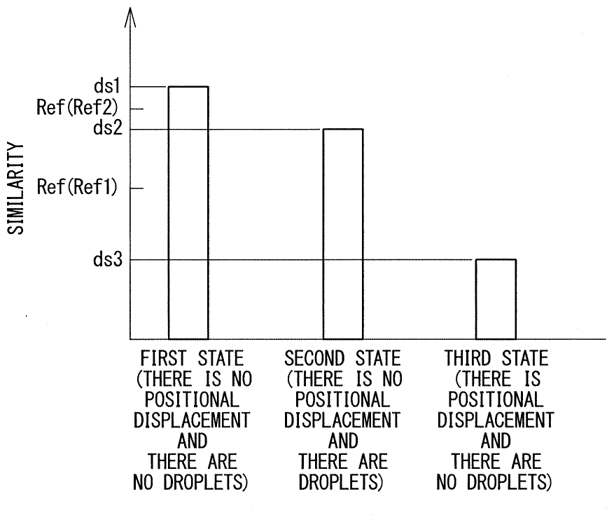

Next, it is contemplated to suppress erroneous determination by setting the threshold Ref. In the present embodiment, the similarity is investigated by an experiment. FIG. 14 is a bar graph schematically illustrating similarity as an experimental result. In the experiment, the camera 70 generates a captured image in each of the following three states, and the controller 9 calculates the first similarity DS1 between the first determination region R11 and the first reference image M11 and the second similarity DS2 between the second determination region R12 and the second reference image M12.

In a first state, the droplets L1 are not attached to the outer peripheral surface of the guard portion 40, and the guard portion 40 normally stops at the guard standby position (see FIG. 8). In a second state, although the droplets L1 are attached to the outer peripheral surface of the guard portion 40, the guard portion 40 normally stops at the guard standby position (see FIG. 13). In a third state, the droplets L1 are not attached to the outer peripheral surface of the guard portion 40, and the guard portion 40 is shifted from the guard standby position and stops. As a specific example, in the third state, the height position of the upper end peripheral edge portion of the outer guard 43 coincides with or is slightly lower than the height position of the upper surface 21a of the spin base 21. In addition, here, in each of the first state to the third state, the camera 70 captures an image a plurality of times, and the controller 9 calculates the first similarity DS1 and the second similarity DS2 each time.

According to the experimental result, the minimum value of the first similarity DS1 and the second similarity DS2 in the first state is a similarity value sd1 (about 0.99). The minimum value of the first similarity DS1 and the second similarity DS2 in the second state is lower than the similarity value sd1 and is a similarity value sd2 (about 0.93). The maximum value of the first similarity DS1 and the second similarity DS2 in the third state is lower than the similarity value sd2 and is a similarity value sd3 (less than about 0.5).

That is, when the droplets L1 are attached to the outer peripheral surface of the guard portion 40, if the guard portion 40 normally stops at the guard standby position, the similarity may be less than the similarity value sd1 but is not less than the similarity value sd2. Further, when the height position of the upper end peripheral edge portion of the outer guard 43 is equal to or less than the height position of the upper surface 21a of the spin base 21, it is possible to avoid collision between the hand of the main conveyance robot 103 and the guard portion 40.

Therefore, the threshold Ref is preferably set to a value (hereinafter, referred to as a first threshold Ref1) lower than the similarity value sd2 (corresponding to a first value) and higher than the similarity value sd3. Accordingly, the guard determination unit 91 determines that the guard portion 40 is normal even in the second state. Therefore, erroneous detection of abnormality in the second state can be avoided.

When the upper end peripheral edge portion of the outer guard 43 is at a position higher than the upper surface 21a of the spin base 21, the guard determination unit 91 can appropriately detect the abnormality of the guard portion 40. Therefore, collision between the hand of the main conveyance robot 103 and the guard portion 40 can be appropriately avoided.

### Shape Abnormality

Although the description has been given focusing on the abnormality related to the position of the guard portion 40 in the above example, the guard determination unit 91 can detect the abnormality even when the abnormality related to the shape of the guard portion 40 occurs. This is because, when an abnormality has occurred in the shape of the guard portion 40 included in the captured image, the similarity between the captured image and the reference image decreases, so that the guard determination unit 91 can detect the abnormality of the guard portion 40 by the above-described determination based on the similarity.

For example, when the outer guard 43 is provisionally determined to be normal in the first determination region R11 and the outer guard 43 is provisionally determined to be abnormal in the second determination region R12, there is a possibility that an abnormality has occurred in the shape of the upper end peripheral edge portion of the outer guard 43. The guard determination unit 91 can also detect such a shape abnormality.

### Second Embodiment

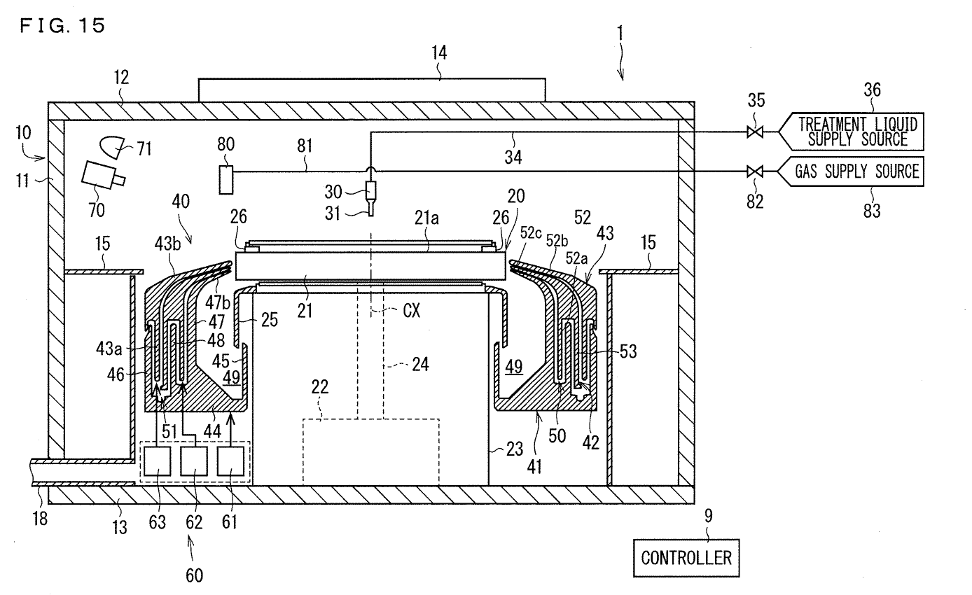

FIG. 15 is a view schematically illustrating an example of a configuration of a treatment unit 1 according to a second embodiment. Compared with the first embodiment, the treatment unit 1 further includes a gas nozzle 80. The gas nozzle 80 is provided in the chamber 10. The discharge port of the gas nozzle 80 faces the guard portion 40, and the gas nozzle 80 discharges the gas from the discharge port toward the guard portion 40 to blow off the droplets L1 attached to the guard portion 40. The flow rate of the gas is set to a value at which the droplets L1 can be sufficiently blown off. The flow rate of the gas is set to, for example, about 50 L (liter)/min or more and 150 L/min or less.

The gas nozzle 80 is connected to a gas supply source 83 via a gas supply pipe 81. The gas supply source 83 includes a cylinder that stores gas. The gas supply pipe 81 is provided with a valve 82. The valve 82 opens and closes a flow path of the gas supply pipe 81. When the valve 82 is opened, the gas supply source 83 supplies gas to the gas nozzle 80 through the gas supply pipe 81. The gas includes, for example, an inert gas. As the inert gas, for example, at least one of a rare gas such as an argon gas and a nitrogen gas can be adopted.

The gas nozzle 80 may discharge the gas to a portion of the guard portion 40 that appears in each of the determination region R1 and the determination region R2 (hereinafter, referred to as a portion to be captured). A plurality of gas nozzles 80 may be provided according to a plurality of portions to be captured of the guard portion 40. The gas nozzle 80 may be provided so as to be immovable in the chamber 10, or may be provided so as to be movable to each position where gas can be supplied to each portion to be captured by a gas nozzle moving mechanism (not illustrated). The gas nozzle moving mechanism is not particularly limited, but may have an arm turning mechanism similar to that of the first nozzle 30, or may have a linear motion mechanism including a ball screw mechanism and a motor. The gas nozzle 80 may be attached to the discharge head 31 at the tip of the nozzle arm 32. In this case, the gas nozzle 80 moves integrally with the first nozzle 30. Alternatively, the gas nozzle 80 may be attached to the discharge head 31A at the tip of the nozzle arm 32A, or may be attached to the discharge head 31B at the tip of the nozzle arm 32B.

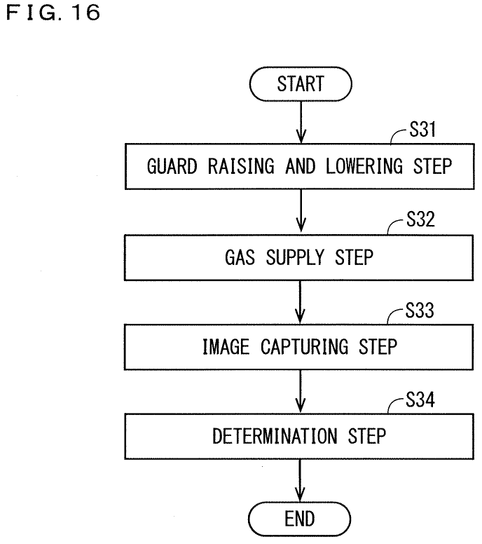

FIG. 16 is a flowchart illustrating an example of guard monitoring processing according to the second embodiment. First, similarly to step S11, the guard raising and lowering mechanism 60 moves the guard portion 40 to a predetermined height position (step S31: guard raising and lowering step). Here, it is assumed that the guard raising and lowering mechanism 60 moves the guard portion 40 to the guard standby position as a predetermined height position.

Next, the treatment unit 1 causes the gas nozzle 80 to discharge gas toward the portion to be captured of the guard portion 40 (step S32: gas supply step). Specifically, the gas nozzle 80 discharges the gas toward the portion to be captured that appears in the determination region R1. Therefore, even if the droplets L1 are attached to the portion to be captured, the droplets L1 are blown off by the gas. When a predetermined time set to a time sufficient to blow off the droplets L1 has elapsed from the start of the discharge of the gas, the treatment unit 1 stops the supply of the gas from the gas nozzle 80. The predetermined time is set to, for example, 0.1 seconds or more and 30 seconds or less.

Next, similarly to step S12, the camera 70 captures an image of the image capturing region to generate a captured image, and outputs the captured image to the controller 9 (step S33: image capturing step). Since the droplets L1 attached to the portion to be captured are blown off by the immediately preceding gas supply step, the determination region R1 of the captured image includes few or no droplets L1.

Next, similarly to step S13, the guard determination unit 91 determines the presence or absence of the abnormality related to the guard portion 40 based on the pixel value in the determination region R1 of the captured image (step S34: determination step). Since the determination region R1 includes few or no droplets L1, the guard determination unit 91 can determine the presence or absence of the abnormality with higher determination accuracy. Note that it is not necessary to adopt the first threshold Ref1 illustrated in FIG. 14 as the threshold Ref, and a value (hereinafter, referred to as a second threshold Ref2) lower than the similarity value sd1 (corresponding to a second value) and higher than the similarity value sd2 (corresponding to the first value) may be adopted as the threshold Ref.

When the guard raising and lowering mechanism 60 moves the guard portion 40 to the guard treatment position in the guard raising and lowering step (step S31), the gas nozzle 80 may supply the gas toward the portion to be captured that appears in the determination region R2 in the gas supply step (step S32). As a result, the determination region R2 of the captured image obtained by the subsequent image capturing step (step S33) includes few or no droplets L1. Therefore, in the determination step (step S34), the guard determination unit 91 can determine the presence or absence of the abnormality with higher determination accuracy.

### Modification

When the treatment unit 1 causes the gas nozzle 80 to discharge the gas each time the guard monitoring processing is performed, the consumption amount of the gas increases. Here, it is contemplated to reduce the consumption amount of the gas.

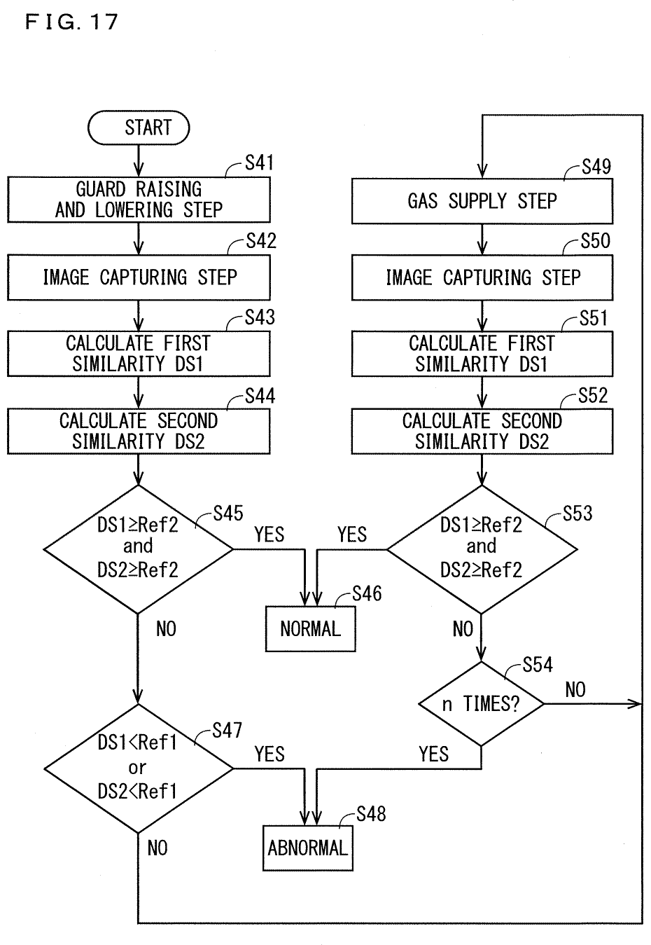

FIG. 17 is a flowchart illustrating a modification of the guard monitoring processing according to the second embodiment. Here, as will be described in detail later, the first threshold Ref1 and the second threshold Ref2 higher than the first threshold Ref1 illustrated in FIG. 14 are appropriately utilized as the threshold Ref.

First, similarly to step S11, the guard raising and lowering mechanism 60 moves the guard portion 40 to a predetermined height position (step S41). Here, the guard raising and lowering mechanism 60 moves the guard portion 40 to the guard standby position.

Next, similarly to step S12, the camera 70 captures an image of the image capturing region to generate a captured image, and outputs the captured image to the controller 9 (step S42).

Next, similarly to step S131, the guard determination unit 91 of the controller 9 calculates the first similarity DS1 between the first determination region R11 of the captured image and the first reference image M11 (step S43), and similarly to step S132, calculates the second similarity DS2 between the second determination region R12 of the captured image and the second reference image M12 (step S44).

Next, the guard determination unit 91 determines whether both the first similarity DS1 and the second similarity DS2 are equal to or greater than the second threshold Ref2 higher than the first threshold Ref1 (step S45). When both the first similarity DS1 and the second similarity DS2 are equal to or greater than the second threshold Ref2, the guard determination unit 91 determines that the guard portion 40 is normal (step S46, corresponding to a first step).

When at least one of the first similarity DS1 and the second similarity DS2 is less than the second threshold Ref2, there is a possibility that an abnormality has occurred or the droplets L1 are attached.

Therefore, the guard determination unit 91 determines whether or not at least one of the first similarity DS1 and the second similarity DS2 is less than the first threshold Ref1 (step S47). When at least one of the first similarity DS1 and the second similarity DS2 is less than the first threshold Ref1, there is a high possibility that an abnormality has occurred, and thus the guard determination unit 91 determines that an abnormality has occurred (step S48).

On the other hand, when both the first similarity DS1 and the second similarity DS2 are equal to or greater than the first threshold Ref1, there is a high possibility that the droplets L1 are attached, and thus the gas nozzle 80 supplies gas to the portion to be captured that appears in the determination region R1 in the guard portion 40 (step S49, corresponding to a second step). As a result, even if the droplets L1 are attached to the portion to be captured, the droplets L1 can be blown off with the gas.

Next, the camera 70 captures an image of the image capturing region to generate a captured image, and outputs the captured image to the controller 9 (step S50, corresponding to a third step).

Next, the guard determination unit 91 determines the presence or absence of the abnormality related to the guard portion 40 based on the captured image and the reference image generated in step S50 (corresponding to a fourth step). More specifically, first, the guard determination unit 91 calculates the first similarity DS1 similarly to step S131 (step S51), and calculates the second similarity DS2 similarly to step S132 (step S52).

Next, the guard determination unit 91 determines whether both the first similarity DS1 and the second similarity DS2 are equal to or greater than the second threshold Ref2 (step S53). When both the first similarity DS1 and the second similarity DS2 are equal to or greater than the second threshold Ref2, the guard determination unit 91 determines that the guard portion 40 is normal (step S46).

On the other hand, when at least one of the first similarity DS1 and the second similarity DS2 is less than the second threshold Ref2, the guard determination unit 91 determines whether the number of times of determination of NO (negative) in step S46 is equal to or greater than the prescribed number of times n (step S54). When the number of times of determination is less than n, the gas supply step (step S49) is executed again. That is, since it is conceivable that the droplets L1 are insufficiently blown off in one gas supply step, the gas supply step is performed again.

When the number of times of determination is n or more, the guard determination unit 91 determines that an abnormality related to the guard portion 40 has occurred (step S48). That is, the guard determination unit 91 determines that an abnormality has occurred when at least one of the first similarity DS1 and the second similarity DS2 after the droplets L1 are blown off in n times of gas supply steps is less than the second threshold Ref2.

As described above, according to the modification, the gas supply step (step S49) is performed when at least one of the first similarity DS1 and the second similarity DS2 is less than the second threshold Ref2 (step S45: NO), and both the first similarity DS1 and the second similarity DS2 are equal to or greater than the first threshold Ref1 (step S47: NO). That is, the treatment unit 1 performs the gas supply step in a situation where there is a high possibility that the droplets L1 are attached to the portion to be captured of the guard portion 40. Therefore, it is possible to reduce the consumption amount of the gas while effectively using the gas.

In the example of FIG. 17, the gas supply step (step S49) can be performed n times, but n may be set to 1. In this case, step S54 is unnecessary.

As described above, although the guard determination method and the substrate treatment apparatus 100 have been described in detail, the above description is illustrative in all aspects, and these are not limited thereto. It is understood that numerous modifications not illustrated can be assumed without departing from the scope of the present disclosure. The configurations described in the above embodiments and modifications can be appropriately combined or omitted as long as they do not contradict each other.

For example, a plurality of image capturing steps and determination steps of the guard monitoring processing may be performed at predetermined time intervals during at least any one of the period during carrying-in and carrying-out of the substrate W, the period during liquid treatment, and the period during drying treatment. That is, the treatment unit 1 may continuously perform the monitoring process on the guard portion 40 within the period.

### EXPLANATION OF REFERENCE SIGNS

1: treatment unit
20: substrate holder (spin chuck)
21: spin base
21a: upper surface
30: liquid nozzle (first nozzle)
41: guard (inner guard)
42: guard (middle guard)
43: guard (outer guard)
30A: liquid nozzle (second nozzle)
30B: liquid nozzle (third nozzle)
80: gas nozzle
9: controller
70: camera
100: substrate treatment apparatus
E1: ellipse
DS1: similarity (first similarity)
DS2: similarity (second similarity)
M11, M21, M31, M41: reference image (first reference image)
M12, M22, M32, M42: reference image (second reference image)
R1, R2: determination region
R11, R21: first determination region
R12, R22: second determination region
Ref1: threshold, first threshold
Ref2: second threshold (threshold)
S11: guard raising and lowering step
S12: image capturing step
S13: determination step
SA1: minor axis
W: substrate

1. A substrate treatment apparatus comprising:
a substrate holder that holds a substrate;
a liquid nozzle that supplies a treatment liquid to said substrate held by said substrate holder;
a guard that has a cylindrical shape, surrounds said substrate holder, and receives said treatment liquid scattered from a peripheral edge of said substrate;
a guard raising and lowering mechanism that raises and lowers said guard;
a camera that is provided obliquely above said substrate holder and captures an image of an image capturing region including said guard to generate a captured image; and
a controller that outputs a control signal for moving said guard to a predetermined height position to said guard raising and lowering mechanism, and determines presence or absence of an abnormality related to a position or a shape of said guard based on said captured image.

2. The substrate treatment apparatus according to claim 1, wherein said controller determines presence or absence of said abnormality based on a determination region including a part of said guard in said captured image.

3. The substrate treatment apparatus according to claim 2, wherein
said determination region includes a first determination region and a second determination region,
said first determination region and said second determination region are set on opposite sides to each other with respect to a minor axis of a virtual ellipse along an upper end peripheral edge portion of said guard in said captured image, and
said controller determines that said guard is normal when temporarily determining that said guard is normal in both said first determination region and said second determination region.

4. The substrate treatment apparatus according to claim 2, wherein said determination region includes at least a part of an upper end peripheral edge portion of said guard when said guard is located at said predetermined height position, and is set to a region not including said substrate.

5. The substrate treatment apparatus according to claim 2, wherein
said predetermined height position is a guard standby position where an upper end peripheral edge portion of said guard is lower than an upper surface of a spin base of said substrate holder facing a lower surface of said substrate in a vertical direction, and
said determination region is set to a region including at least a part of a peripheral edge portion on a front side as viewed from said camera in said upper end peripheral edge portion of said guard when said guard is located at said predetermined height position.

6. The substrate treatment apparatus according to claim 2, wherein
said predetermined height position is a guard treatment position where an upper end peripheral edge portion of said guard is above an upper surface of said substrate held by said substrate holder, and
said determination region is set to a region including a peripheral edge portion on a back side as viewed from said camera in the upper end peripheral edge portion of said guard when said guard is located at said predetermined height position.

7. The substrate treatment apparatus according to claim 6, wherein
said controller moves at least one of a plurality of said guards to said guard treatment position, and
said determination region is set to a region including said upper end peripheral edge portion of each of said plurality of guards when each of said plurality of guards is located at said guard treatment position.

8. The substrate treatment apparatus according to claim 2, wherein
said controller determines that said guard is normal when similarity between said determination region and a normal reference image is equal to or greater than a threshold, and
said threshold is set to be lower than a value of similarity between said determination region of said captured image captured when said guard is located at said predetermined height position and a droplet is attached to said guard and said reference image.

9. The substrate treatment apparatus according to claim 1, further comprising a gas nozzle that supplies gas to said guard to blow off droplet attached to said guard.

10. The substrate treatment apparatus according to claim 2, comprising a gas nozzle that supplies gas to said guard to blow off droplet attached to said guard,
wherein said controller includes:
a first step of determining that said guard is normal when similarity between said determination region and a normal reference image is equal to or greater than a second threshold higher than a first threshold;
a second step of supplying gas to said gas nozzle toward a portion to be captured of said guard that appears in said determination region when said similarity is less than said second threshold and equal to or greater than said first threshold;
a third step of causing said camera to capture said image capturing region and generate said captured image after said second step; and
a fourth step of determining presence or absence of said abnormality based on said similarity between said determination region of said captured image generated in said third step and said reference image,
said first threshold is set to be lower than a first value of similarity between said determination region of said captured image captured when said guard is located at said predetermined height position and a droplet is attached to said portion to be captured of said guard and said reference image, and
said second threshold is set to be lower than a second value of similarity between said determination region of said captured image captured when said guard is located at said predetermined height position and no droplets are attached to said portion to be captured of said guard and said reference image, and to be higher than said first value.

11. A guard determination method comprising:
a guard raising and lowering step of moving a guard that has a cylindrical shape and surrounds a substrate holder holding a substrate to a predetermined height position;
an image capturing step of capturing an image of an image capturing region including said guard by a camera provided above said substrate holder and generating a captured image; and
a determination step of determining whether or not an abnormality related to a position or a shape of said guard has occurred based on said captured image.

12. The guard determination method according to claim 11, wherein, in said determination step, the presence or absence of said abnormality is determined based on a determination region including a part of said guard in said captured image.

13. The guard determination method according to claim 12, wherein
said determination region includes a first determination region and a second determination region,
said first determination region and said second determination region are set on opposite sides to each other with respect to a minor axis of a virtual ellipse along an upper end peripheral edge portion of said guard in said captured image, and
in said determination step, it is determined that said guard is normal when temporarily determining that said guard is normal in both said first determination region and said second determination region.

14. The guard determination method according to claim 12, wherein said determination region includes at least a part of an upper end peripheral edge portion of said guard when said guard is located at said predetermined height position, and is set to a region not including said substrate.

15. The guard determination method according to claim 12, wherein
said predetermined height position is a guard standby position where an upper end peripheral edge portion of said guard is lower than an upper surface of a spin base of said substrate holder facing a lower surface of said substrate in a vertical direction, and
said determination region is set to a region including at least a part of a peripheral edge portion on a front side as viewed from said camera in said upper end peripheral edge portion of said guard when said guard is located at said predetermined height position.

16. The guard determination method according to claim 12, wherein
said predetermined height position is a guard treatment position where an upper end peripheral edge portion of said guard is above an upper surface of said substrate held by said substrate holder, and
said determination region is set to a region including a peripheral edge portion on a back side as viewed from said camera in the upper end peripheral edge portion of said guard when said guard is located at said predetermined height position.

17. The guard determination method according to claim 16, wherein
in said guard raising and lowering step, at least one of a plurality of said guards is moved to said guard treatment position, and
said determination region is set to a region including said upper end peripheral edge portion of each of said plurality of guards when each of said plurality of guards is located at said guard treatment position.

18. The guard determination method according to claim 12, wherein
in said determination step, it is determined that said guard is normal when similarity between said determination region and a normal reference image is equal to or greater than a threshold, and
said threshold is set to be lower than a value of similarity between said determination region of said captured image captured when said guard is located at said predetermined height position and a droplet is attached to said guard and said reference image.

19. The guard determination method according to claim 11, further comprising a gas supply step of blowing off droplet attached to said guard with gas before said image capturing step.

20. The guard determination method according to claim 12, wherein
said determination step includes:
a first step of determining that said guard is normal when similarity between said determination region and a normal reference image is equal to or greater than a second threshold higher than a first threshold;
a second step of supplying gas to a portion to be captured of said guard that appears in said determination region when said similarity is less than said second threshold and equal to or greater than said first threshold;
a third step of capturing, by said camera, said image capturing region and generate said captured image after said second step; and
a fourth step of determining presence or absence of said abnormality based on said similarity between said determination region of said captured image generated in said third step and said reference image,
said first threshold is set to be lower than a first value of similarity between said determination region of said captured image captured when said guard is located at said predetermined height position and a droplet is attached to said portion to be captured of said guard and said reference image, and
said second threshold is set to be lower than a second value of similarity between said determination region of said captured image captured when said guard is located at said predetermined height position and no droplets are attached to said portion to be captured of said guard and said reference image, and to be higher than said first value.
